(19) United States
(12) Patent Application Publication
(10) Pub. No.: US 2013/0135320 A1
(43) Pub. Date: May 30, 2013

(54) TRI-STATE MEMS DEVICE AND DRIVE SCHEMES

(71) Applicants: Alok Govil, Santa Clara, CA (US); Marc M. Mignard, San Jose, CA (US)

(72) Inventors: Alok Govil, Santa Clara, CA (US); Marc M. Mignard, San Jose, CA (US)

(73) Assignee: QUALCOMM MEMS Technologies, Inc., San Diego, CA (US)

(21) Appl. No.: 13/308,385

(22) Filed: Nov. 30, 2011

(51) Int. Cl. G06T 1/00; H02N 1/00; H01L 41/04; G02B 26/00; G06F 3/038

(52) U.S. Cl. 345/501; 359/290; 345/211; 318/116; 310/309

(57) ABSTRACT

This disclosure provides systems, methods and apparatus, including computer programs encoded on computer storage media, for driving an array of tri-state devices. The array of tri-state devices may form an array of display elements, and the array may be passively addressed. According to one aspect, the array includes two segment lines and one common line connected to each tri-state display element. According to another aspect, the array includes two common lines and one segment line connected to each tri-state display element.

### TECHNICAL FIELD

This disclosure relates methods and systems for driving an array of tri-state MEMS elements.

### DESCRIPTION OF THE RELATED TECHNOLOGY

Electromechanical systems include devices having electrical and mechanical elements, actuators, transducers, sensors, optical components (e.g., mirrors) and electronics. Electromechanical systems can be manufactured at a variety of scales including, but not limited to, microscales and nanoscales. For example, microelectromechanical systems (MEMS) devices can include structures having sizes ranging from about a micron to hundreds of microns or more. Nanoelectromechanical systems (NEMS) devices can include structures having sizes smaller than a micron including, for example, sizes smaller than several hundred nanometers. Electromechanical elements may be created using deposition, etching, lithography, and/or other micromachining processes that etch away parts of substrates and/or deposited material layers, or that add layers to form electrical and electromechanical devices.

One type of electromechanical systems device is called an interferometric modulator (IMOD). As used herein, the term interferometric modulator or interferometric light modulator refers to a device that selectively absorbs and/or reflects light using the principles of optical interference. In some implementations, an interferometric modulator may include a pair of conductive plates, one or both of which may be transparent and/or reflective, wholly or in part, and capable of relative motion upon application of an appropriate electrical signal. In an implementation, one plate may include a stationary layer deposited on a substrate and the other plate may include a reflective membrane separated from the stationary layer by an air gap. The position of one plate in relation to another can change the optical interference of light incident on the interferometric modulator. Interferometric modulator devices have a wide range of applications, and are anticipated to be used in improving existing products and creating new products, especially those with display capabilities.

### SUMMARY

The systems, methods and devices of the disclosure each have several innovative aspects, no single one of which is solely responsible for the desirable attributes disclosed herein.

One innovative aspect of the subject matter described in this disclosure can be implemented in an apparatus including a microelectromechanical systems (MEMS) device. In this aspect, the MEMS device may have a first layer, a second layer, and a movable third layer between the first layer and the second layer, the movable third layer configured to be positioned in one of a first position, a second position that is different than the first position, and a third position that is different than the first position and second position. The apparatus may further include a driver configured to apply a first set of voltages to the MEMS device to selectively place the device into one of the first position, second position, and third position. The driver may be further configured to apply a second set of voltages to the MEMS device to maintain the device in the same position it was placed by the first set of voltages.

In another innovative aspect, a method of driving a microelectromechanical systems (MEMS) device is provided, wherein the MEMS device may have a first layer, a second layer, and a movable third layer between the first layer and the second layer, the movable third layer configured to be positioned in one of a first position, a second position that is different than the first position, and a third position that is different than the first position and second position. The method may include applying a first set of voltages to the MEMS device to selectively place the device into one of the first position, second position, and third position, and applying a second set of voltages to the device to maintain the device in the same position it was placed by the first set of voltages.

In another innovative aspect, an apparatus comprises a microelectromechanical systems (MEMS) device having a first layer, a second layer, and a movable third layer between the first layer and the second layer, the movable third layer configured to be positioned in one of a first position, a second position that is different than the first position, and a third position that is different than the first position and second position. The apparatus further includes means for applying a first set of voltages to the MEMS device to selectively place the MEMS device into one of the first position, second position, and third position, and means for applying a second set of voltages to the MEMS device to maintain the device in the same position it was placed by the first set of voltages.

Details of one or more implementations of the subject matter described in this specification are set forth in the accompanying drawings and the description below. Other features, aspects, and advantages will become apparent from the description, the drawings, and the claims. Note that the relative dimensions of the following figures may not be drawn to scale.

### BRIEF DESCRIPTION OF THE DRAWINGS

FIG. 1 shows an example of an isometric view depicting two adjacent pixels in a series of pixels of an interferometric modulator (IMOD) display device.

FIG. 2 shows an example of a system block diagram illustrating an electronic device incorporating a 3×3 interferometric modulator display.

FIG. 3 shows an example of a diagram illustrating movable reflective layer position versus applied voltage for the interferometric modulator of FIG. 1.

FIG. 4 shows an example of a table illustrating various states of an interferometric modulator when various common and segment voltages are applied.

FIG. 5A shows an example of a diagram illustrating a frame of display data in the 3×3 interferometric modulator display of FIG. 2.

FIG. 5B shows an example of a timing diagram for common and segment signals that may be used to write the frame of display data illustrated in FIG. 5A.

FIG. 6A shows an example of a partial cross-section of the interferometric modulator display of FIG. 1.

FIGS. 6B-6E show examples of cross-sections of varying implementations of interferometric modulators.

FIG. 7 shows an example of a flow diagram illustrating a manufacturing process for an interferometric modulator.

FIGS. 8A-8E show examples of cross-sectional schematic illustrations of various stages in a method of making an interferometric modulator.

FIG. 9 is a cross-section of an implementation of a display element having two fixed layers and a movable third layer.

FIG. 10 shows an example of a diagram illustrating a movable middle layer position versus applied voltage for the interferometric modulator of FIG. 9.

FIG. 11 illustrates an example of an array of tri-state display elements that can be written with a passive matrix drive scheme having two segment lines and one common line according to some implementations.

FIG. 12A is an example of voltages applied to the common lines and segment lines in a passive matrix drive scheme according to some implementations.

FIG. 12B illustrates a data pattern written to an array of tri-state display elements.

FIG. 12C illustrates an example waveform for driving an array of display elements according to the voltage levels of FIG. 11A to write the data pattern of FIG. 12B.

FIG. 13A is an example of voltages applied to the common lines and segment lines in a passive matrix drive scheme according to some implementations.

FIG. 13B illustrates an example waveform for driving an array of display elements according to the voltage levels of FIG. 12A to write the data pattern of FIG. 12B.

FIG. 14 shows an example of a diagram illustrating a movable middle layer position versus applied voltage for the interferometric modulator of FIG. 9.

FIG. 15 illustrates an example of an array of tri-state display elements that can be written with a passive matrix drive scheme having two common lines and one segment line according to some implementations.

FIG. 16A is an example of voltages applied to the common lines and segment lines in a passive matrix drive scheme according to some implementations.

FIG. 16B illustrates an example waveform for driving a display element by application of the voltages of FIG. 14A to write the data pattern of FIG. 12B.

FIG. 17 illustrates an example of an array of tri-state display elements that can be written with an active matrix drive scheme having plural common lines and one segment line connected to each display element according to some implementations.

FIG. 18 illustrates an example waveform for driving a display element using an active matrix to write the data pattern of FIG. 12B.

FIG. 19 illustrates a flowchart of a method of driving an array of tri-state devices according to some implementations.

FIGS. 20A and 20B show examples of system block diagrams illustrating a display device that includes a plurality of interferometric modulators.

Like reference numbers and designations in the various drawings indicate like elements.

### DETAILED DESCRIPTION

The following detailed description is directed to certain implementations for the purposes of describing the innovative aspects. However, the teachings herein can be applied in a multitude of different ways. The described implementations may be implemented in any device that is configured to display an image, whether in motion (e.g., video) or stationary (e.g., still image), and whether textual, graphical or pictorial. More particularly, it is contemplated that the implementations may be implemented in or associated with a variety of electronic devices such as, but not limited to, mobile telephones, multimedia Internet enabled cellular telephones, mobile television receivers, wireless devices, smartphones, Bluetooth® devices, personal data assistants (PDAs), wireless electronic mail receivers, hand-held or portable computers, netbooks, notebooks, smartbooks, tablets, printers, copiers, scanners, facsimile devices, GPS receivers/navigators, cameras, MP3 players, camcorders, game consoles, wrist watches, clocks, calculators, television monitors, flat panel displays, electronic reading devices (e.g., e-readers), computer monitors, auto displays (e.g., odometer display, etc.), cockpit controls and/or displays, camera view displays (e.g., display of a rear view camera in a vehicle), electronic photographs, electronic billboards or signs, projectors, architectural structures, microwaves, refrigerators, stereo systems, cassette recorders or players, DVD players, CD players, VCRs, radios, portable memory chips, washers, dryers, washer/dryers, parking meters, packaging (e.g., MEMS and non-MEMS), aesthetic structures (e.g., display of images on a piece of jewelry) and a variety of electromechanical systems devices. The teachings herein also can be used in non-display applications such as, but not limited to, electronic switching devices, radio frequency filters, sensors, accelerometers, gyroscopes, motion-sensing devices, magnetometers, inertial components for consumer electronics, parts of consumer electronics products, varactors, liquid crystal devices, electrophoretic devices, drive schemes, manufacturing processes, and electronic test equipment. Thus, the teachings are not intended to be limited to the implementations depicted solely in the figures, but instead have wide applicability as will be readily apparent to a person having ordinary skill in the art.

A display may include an array of tri-state display elements that are arranged at the intersections of driving signal lines or electrode strips. A tri-state display element may include three layers such that each layer is connected to a different signal line in the array. In one aspect, implementations of tri-state display elements can be placed in any one of three different physical states with different optical properties by application of write voltages to the layers. The display elements can then be held in any of the three states with hold voltages to display an image. Some drive schemes to accomplish this are generally referred to as a “passive matrix” drive schemes herein in that there are no local switches at each display element controlling the application of one or more of the drive voltages. Other drive schemes are referred to as “active matrix” and include a local switch associated with each display element.

Particular implementations of the subject matter described in this disclosure can be implemented to realize one or more of the following potential advantages. Some implementations of the drive scheme disclosed herein enable the use of tri-state EMS or MEMS devices (e.g., tri-state IMOD) as display elements in display systems. In general, tri-state display elements provide better gamut and brightness than conventional bi-stable display elements. Further, some implementations of the drive scheme disclosed herein are applicable to both passively addressed display arrays and actively addressed display arrays, thus, allowing the use of tri-state display elements in a wide variety of display systems.

An example of a suitable EMS or MEMS device, to which the described implementations may apply, is a reflective display device. Reflective display devices can incorporate interferometric modulators (IMODs) to selectively absorb and/or reflect light incident thereon using principles of optical interference. IMODs can include an absorber, a reflector that is movable with respect to the absorber, and an optical resonant cavity defined between the absorber and the reflector. The reflector can be moved to two or more different positions, which can change the size of the optical resonant cavity and thereby affect the reflectance of the interferometric modulator. The reflectance spectrums of IMODs can create fairly broad spectral bands which can be shifted across the visible wavelengths to generate different colors. The position of the spectral band can be adjusted by changing the thickness of the optical resonant cavity, i.e., by changing the position of the reflector.

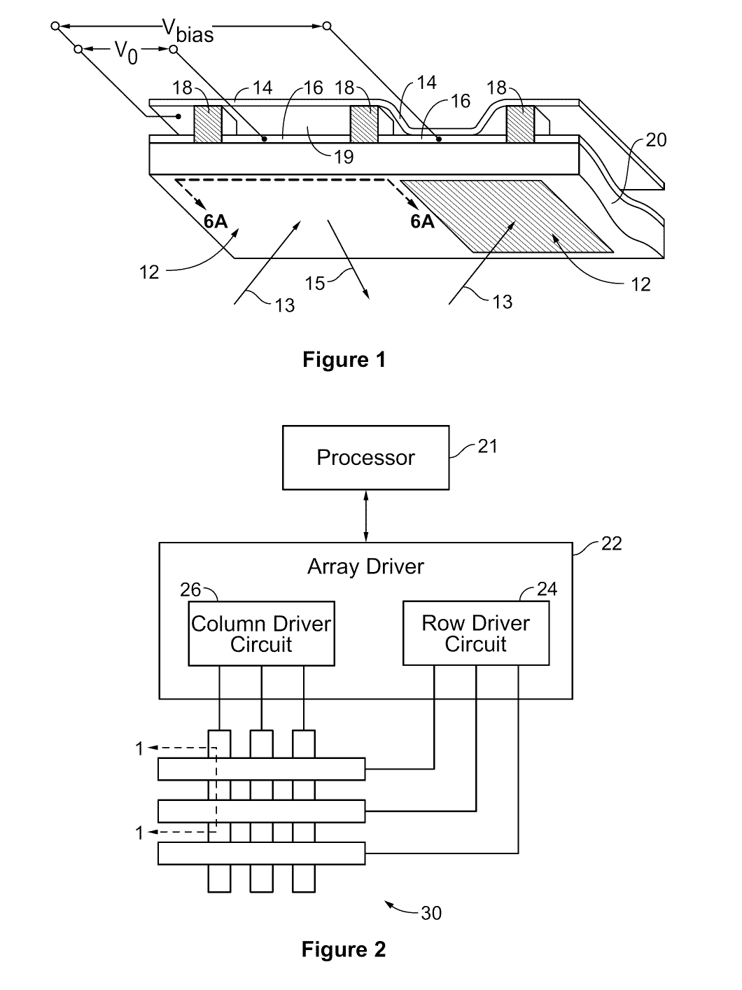

FIG. 1 shows an example of an isometric view depicting two adjacent pixels in a series of pixels of an interferometric modulator (IMOD) display device. The IMOD display device includes one or more interferometric MEMS display elements. In these devices, the pixels of the MEMS display elements can be in either a bright or dark state. In the bright (“relaxed,” “open” or “on”) state, the display element reflects a large portion of incident visible light, e.g., to a user. Conversely, in the dark (“actuated,” “closed” or “off”) state, the display element reflects little incident visible light. In some implementations, the light reflectance properties of the on and off states may be reversed. MEMS pixels can be configured to reflect predominantly at particular wavelengths allowing for a color display in addition to black and white.

The IMOD display device can include a row/column array of IMODs. Each IMOD can include a pair of reflective layers, i.e., a movable reflective layer and a fixed partially reflective layer, positioned at a variable and controllable distance from each other to form an air gap (also referred to as an optical gap or cavity). The movable reflective layer may be moved between at least two positions. In a first position, i.e., a relaxed position, the movable reflective layer can be positioned at a relatively large distance from the fixed partially reflective layer. In a second position, i.e., an actuated position, the movable reflective layer can be positioned more closely to the partially reflective layer. Incident light that reflects from the two layers can interfere constructively or destructively depending on the position of the movable reflective layer, producing either an overall reflective or non-reflective state for each pixel. In some implementations, the IMOD may be in a reflective state when unactuated, reflecting light within the visible spectrum, and may be in a dark state when actuated, reflecting light outside of the visible range (e.g., infrared light). In some other implementations, however, an IMOD may be in a dark state when unactuated, and in a reflective state when actuated. In some implementations, the introduction of an applied voltage can drive the pixels to change states. In some other implementations, an applied charge can drive the pixels to change states.

The depicted portion of the pixel array in FIG. 1 includes two adjacent interferometric modulators 12. In the IMOD 12 on the left (as illustrated), a movable reflective layer 14 is illustrated in a relaxed position at a predetermined distance from an optical stack 16, which includes a partially reflective layer. The voltage V₀ applied across the IMOD 12 on the left is insufficient to cause actuation of the movable reflective layer 14. In the IMOD 12 on the right, the movable reflective layer 14 is illustrated in an actuated position near or adjacent the optical stack 16. The voltage V_{bias} applied across the IMOD 12 on the right is sufficient to maintain the movable reflective layer 14 in the actuated position.

In FIG. 1, the reflective properties of pixels 12 are generally illustrated with arrows indicating light 13 incident upon the pixels 12, and light 15 reflecting from the pixel 12 on the left. Although not illustrated in detail, it will be understood by a person having ordinary skill in the art that most of the light 13 incident upon the pixels 12 will be transmitted through the transparent substrate 20, toward the optical stack 16. A portion of the light incident upon the optical stack 16 will be transmitted through the partially reflective layer of the optical stack 16, and a portion will be reflected back through the transparent substrate 20. The portion of light 13 that is transmitted through the optical stack 16 will be reflected at the movable reflective layer 14, back toward (and through) the transparent substrate 20. Interference (constructive or destructive) between the light reflected from the partially reflective layer of the optical stack 16 and the light reflected from the movable reflective layer 14 will determine the wavelength(s) of light 15 reflected from the pixel 12.

The optical stack 16 can include a single layer or several layers. The layer(s) can include one or more of an electrode layer, a partially reflective and partially transmissive layer and a transparent dielectric layer. In some implementations, the optical stack 16 is electrically conductive, partially transparent and partially reflective, and may be fabricated, for example, by depositing one or more of the above layers onto a transparent substrate 20. The electrode layer can be formed from a variety of materials, such as various metals, for example indium tin oxide (ITO). The partially reflective layer can be formed from a variety of materials that are partially reflective, such as various metals, e.g., chromium (Cr), semiconductors, and dielectrics. The partially reflective layer can be formed of one or more layers of materials, and each of the layers can be formed of a single material or a combination of materials. In some implementations, the optical stack 16 can include a single semi-transparent thickness of metal or semiconductor which serves as both an optical absorber and conductor, while different, more conductive layers or portions (e.g., of the optical stack 16 or of other structures of the IMOD) can serve to bus signals between IMOD pixels. The optical stack 16 also can include one or more insulating or dielectric layers covering one or more conductive layers or a conductive/absorptive layer.

In some implementations, the layer(s) of the optical stack 16 can be patterned into parallel strips, and may form row electrodes in a display device as described further below. As will be understood by one having skill in the art, the term “patterned” is used herein to refer to masking as well as etching processes. In some implementations, a highly conductive and reflective material, such as aluminum (Al), may be used for the movable reflective layer 14, and these strips may form column electrodes in a display device. The movable reflective layer 14 may be formed as a series of parallel strips of a deposited metal layer or layers (orthogonal to the row electrodes of the optical stack 16) to form columns deposited on top of posts 18 and an intervening sacrificial material deposited between the posts 18. When the sacrificial material is etched away, a defined gap 19, or optical cavity, can be formed between the movable reflective layer 14 and the optical stack 16. In some implementations, the spacing between posts 18 may be approximately 1-1000 um, while the gap 19 may be less than 10,000 Angstroms (Å).

In some implementations, each pixel of the IMOD, whether in the actuated or relaxed state, is essentially a capacitor formed by the fixed and moving reflective layers. When no voltage is applied, the movable reflective layer 14 remains in a mechanically relaxed state, as illustrated by the pixel 12 on the left in FIG. 1, with the gap 19 between the movable reflective layer 14 and optical stack 16. However, when a potential difference, e.g., voltage, is applied to at least one of a selected row and column, the capacitor formed at the intersection of the row and column electrodes at the corresponding pixel becomes charged, and electrostatic forces pull the electrodes together. If the applied voltage exceeds a threshold, the movable reflective layer 14 can deform and move near or against the optical stack 16. A dielectric layer (not shown) within the optical stack 16 may prevent shorting and control the separation distance between the layers 14 and 16, as illustrated by the actuated pixel 12 on the right in FIG. 1. The behavior is the same regardless of the polarity of the applied potential difference. Though a series of pixels in an array may be referred to in some instances as “rows” or “columns,” a person having ordinary skill in the art will readily understand that referring to one direction as a “row” and another as a “column” is arbitrary. Restated, in some orientations, the rows can be considered columns, and the columns considered to be rows. Furthermore, the display elements may be evenly arranged in orthogonal rows and columns (an “array”), or arranged in non-linear configurations, for example, having certain positional offsets with respect to one another (a “mosaic”). The terms “array” and “mosaic” may refer to either configuration. Thus, although the display is referred to as including an “array” or “mosaic,” the elements themselves need not be arranged orthogonally to one another, or disposed in an even distribution, in any instance, but may include arrangements having asymmetric shapes and unevenly distributed elements.

FIG. 2 shows an example of a system block diagram illustrating an electronic device incorporating a 3×3 interferometric modulator display. The electronic device includes a processor 21 that may be configured to execute one or more software modules. In addition to executing an operating system, the processor 21 may be configured to execute one or more software applications, including a web browser, a telephone application, an email program, or any other software application.

The processor 21 can be configured to communicate with an array driver 22. The array driver 22 can include a row driver circuit 24 and a column driver circuit 26 that provide signals to, e.g., a display array or panel 30. The cross section of the IMOD display device illustrated in FIG. 1 is shown by the lines 1-1 in FIG. 2. Although FIG. 2 illustrates a 3×3 array of IMODs for the sake of clarity, the display array 30 may contain a very large number of IMODs, and may have a different number of IMODs in rows than in columns, and vice versa.

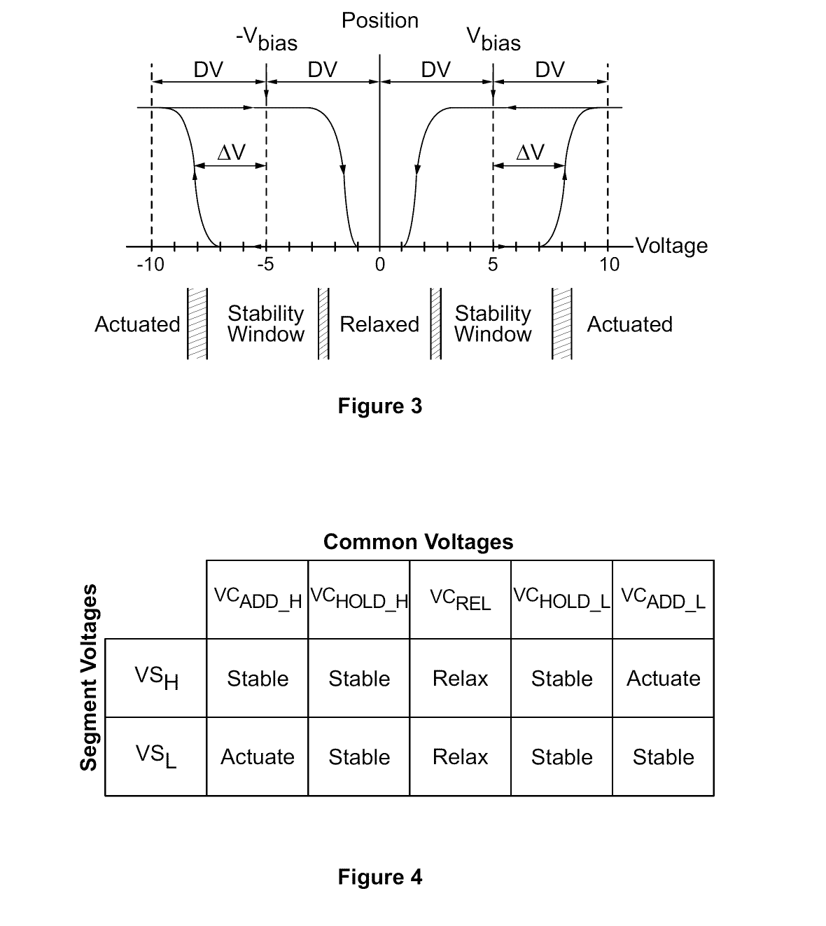

FIG. 3 shows an example of a diagram illustrating movable reflective layer position versus applied voltage for the interferometric modulator of FIG. 1. For MEMS interferometric modulators, the row/column (i.e., common/segment) write procedure may take advantage of a hysteresis property of these devices as illustrated in FIG. 3. An interferometric modulator may require, for example, about a 10-volt potential difference to cause the movable reflective layer, or mirror, to change from the relaxed state to the actuated state. When the voltage is reduced from that value, the movable reflective layer maintains its state as the voltage drops back below, e.g., 10-volts, however, the movable reflective layer does not relax completely until the voltage drops below 2-volts. Thus, a range of voltage, approximately 3 to 7-volts, as shown in FIG. 3, exists where there is a window of applied voltage within which the device is stable in either the relaxed or actuated state. This is referred to herein as the “hysteresis window” or “stability window.” The “hysteresis window” or “stability window” may be centered about the voltage V_{bias}. In addition, the width of the window may be defined such that half of the window width corresponds to a voltage value ΔV as illustrated in FIG. 3. In the example of FIG. 3, the value of +V_{bias} is +5 volts, and the value for −V_{bias} is −5 volts, and the value for ΔV is 3 volts. For a display array 30 having the hysteresis characteristics of FIG. 3, the row/column write procedure can be designed to address one or more rows at a time, such that during the addressing of a given row, pixels in the addressed row that are to be actuated are exposed to a voltage difference of about 10-volts, and pixels that are to be relaxed are exposed to a voltage difference of near zero volts. After addressing, the pixels are exposed to a steady state or bias voltage difference of approximately 5-volts such that they remain in the previous strobing state. In this example, after being addressed, each pixel sees a potential difference within the “stability window” of about 3-7-volts. This hysteresis property feature enables the pixel design, e.g., illustrated in FIG. 1, to remain stable in either an actuated or relaxed pre-existing state under the same applied voltage conditions. Since each IMOD pixel, whether in the actuated or relaxed state, is essentially a capacitor formed by the fixed and moving reflective layers, this stable state can be held at a steady voltage within the hysteresis window without substantially consuming or losing power. Moreover, essentially little or no current flows into the IMOD pixel if the applied voltage potential remains substantially fixed.

In some implementations, a frame of an image may be created by applying data signals in the form of “segment” voltages along the set of column electrodes, in accordance with the desired change (if any) to the state of the pixels in a given row. Each row of the array can be addressed in turn, such that the frame is written one row at a time. To write the desired data to the pixels in a first row, segment voltages corresponding to the desired state of the pixels in the first row can be applied on the column electrodes, and a first row pulse in the form of a specific “common” voltage or signal can be applied to the first row electrode. The set of segment voltages can then be changed to correspond to the desired change (if any) to the state of the pixels in the second row, and a second common voltage can be applied to the second row electrode. In some implementations, the pixels in the first row are unaffected by the change in the segment voltages applied along the column electrodes, and remain in the state they were set to during the first common voltage row pulse. This process may be repeated for the entire series of rows, or alternatively, columns, in a sequential fashion to produce the image frame. The frames can be refreshed and/or updated with new image data by continually repeating this process at some desired number of frames per second.

The combination of segment and common signals applied across each pixel (that is, the potential difference across each pixel) determines the resulting state of each pixel. FIG. 4 shows an example of a table illustrating various states of an interferometric modulator when various common and segment voltages are applied. As will be readily understood by one having ordinary skill in the art, the “segment” voltages can be applied to either the column electrodes or the row electrodes, and the “common” voltages can be applied to the other of the column electrodes or the row electrodes.

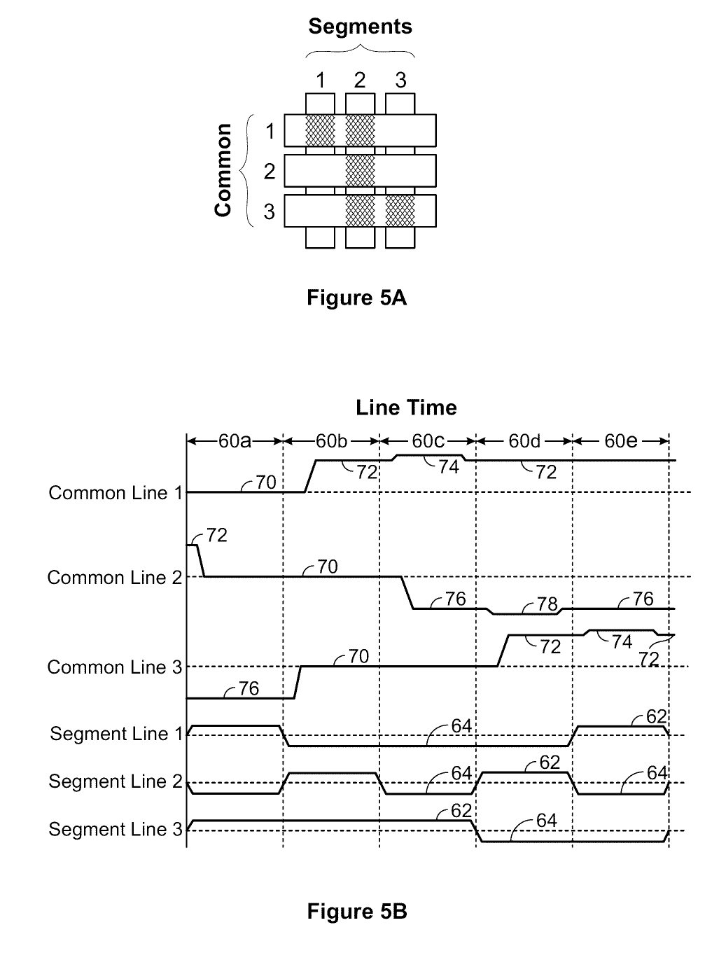

As illustrated in FIG. 4 (as well as in the timing diagram shown in FIG. 5B), when a release voltage VC_{REL} is applied along a common line, all interferometric modulator elements along the common line will be placed in a relaxed state, alternatively referred to as a released or unactuated state, regardless of the voltage applied along the segment lines, i.e., high segment voltage VS_{H} and low segment voltage VS_{L}. In particular, when the release voltage VC_{REL} is applied along a common line, the potential voltage across the modulator (alternatively referred to as a pixel voltage) is within the relaxation window (see FIG. 3, also referred to as a release window) both when the high segment voltage VS_{H} and the low segment voltage VS_{L} are applied along the corresponding segment line for that pixel.

When a hold voltage is applied on a common line, such as a high hold voltage VC_{HOLD}_{_{—}}_{H} or a low hold voltage VC_{HOLD}_{_{—}}_{L}, the state of the interferometric modulator will remain constant. For example, a relaxed IMOD will remain in a relaxed position, and an actuated IMOD will remain in an actuated position. The hold voltages can be selected such that the pixel voltage will remain within a stability window both when the high segment voltage VS_{H} and the low segment voltage VS_{L} are applied along the corresponding segment line. Thus, the segment voltage swing, i.e., the difference between the high VS_{H} and low segment voltage VS_{L}, is less than the width of either the positive or the negative stability window.

When an addressing, or actuation, voltage is applied on a common line, such as a high addressing voltage VC_{ADD}_{_{—}}_{H} or a low addressing voltage VC_{ADD}_{_{—}}_{L}, data can be selectively written to the modulators along that line by application of segment voltages along the respective segment lines. The segment voltages may be selected such that actuation is dependent upon the segment voltage applied. When an addressing voltage is applied along a common line, application of one segment voltage will result in a pixel voltage within a stability window, causing the pixel to remain unactuated. In contrast, application of the other segment voltage will result in a pixel voltage beyond the stability window, resulting in actuation of the pixel. The particular segment voltage which causes actuation can vary depending upon which addressing voltage is used. In some implementations, when the high addressing voltage VC_{ADD}_{_{—}}_{H} is applied along the common line, application of the high segment voltage VS_{H} can cause a modulator to remain in its current position, while application of the low segment voltage VS_{L} can cause actuation of the modulator. As a corollary, the effect of the segment voltages can be the opposite when a low addressing voltage VC_{ADD}_{_{—}}_{L} is applied, with high segment voltage VS_{H} causing actuation of the modulator, and low segment voltage VS_{L} having no effect (i.e., remaining stable) on the state of the modulator.

In some implementations, hold voltages, address voltages, and segment voltages may be used which always produce the same polarity potential difference across the modulators. In some other implementations, signals can be used which alternate the polarity of the potential difference of the modulators. Alternation of the polarity across the modulators (that is, alternation of the polarity of write procedures) may reduce or inhibit charge accumulation which could occur after repeated write operations of a single polarity.

FIG. 5A shows an example of a diagram illustrating a frame of display data in the 3×3 interferometric modulator display of FIG. 2. FIG. 5B shows an example of a timing diagram for common and segment signals that may be used to write the frame of display data illustrated in FIG. 5A. The signals can be applied to the, e.g., 3×3 array of FIG. 2, which will ultimately result in the line time 60e display arrangement illustrated in FIG. 5A. The actuated modulators in FIG. 5A are in a dark-state, i.e., where a substantial portion of the reflected light is outside of the visible spectrum so as to result in a dark appearance to, e.g., a viewer. Prior to writing the frame illustrated in FIG. 5A, the pixels can be in any state, but the write procedure illustrated in the timing diagram of FIG. 5B presumes that each modulator has been released and resides in an unactuated state before the first line time 60a.

During the first line time 60a: a release voltage 70 is applied on common line 1; the voltage applied on common line 2 begins at a high hold voltage 72 and moves to a release voltage 70; and a low hold voltage 76 is applied along common line 3. Thus, the modulators (common 1, segment 1), (1,2) and (1,3) along common line 1 remain in a relaxed, or unactuated, state for the duration of the first line time 60a, the modulators (2,1), (2,2) and (2,3) along common line 2 will move to a relaxed state, and the modulators (3,1), (3,2) and (3,3) along common line 3 will remain in their previous state. With reference to FIG. 4, the segment voltages applied along segment lines 1, 2 and 3 will have no effect on the state of the interferometric modulators, as none of common lines 1, 2 or 3 are being exposed to voltage levels causing actuation during line time 60a (i.e., VC_{REL}—relax and VC_{HOLD}_{_{—}}_{L}—stable).

During the second line time 60b, the voltage on common line 1 moves to a high hold voltage 72, and all modulators along common line 1 remain in a relaxed state regardless of the segment voltage applied because no addressing, or actuation, voltage was applied on the common line 1. The modulators along common line 2 remain in a relaxed state due to the application of the release voltage 70, and the modulators (3,1), (3,2) and (3,3) along common line 3 will relax when the voltage along common line 3 moves to a release voltage 70.

During the third line time 60c, common line 1 is addressed by applying a high address voltage 74 on common line 1. Because a low segment voltage 64 is applied along segment lines 1 and 2 during the application of this address voltage, the pixel voltage across modulators (1,1) and (1,2) is greater than the high end of the positive stability window (i.e., the voltage differential exceeded a predefined threshold) of the modulators, and the modulators (1,1) and (1,2) are actuated. Conversely, because a high segment voltage 62 is applied along segment line 3, the pixel voltage across modulator (1,3) is less than that of modulators (1,1) and (1,2), and remains within the positive stability window of the modulator; modulator (1,3) thus remains relaxed. Also during line time 60c, the voltage along common line 2 decreases to a low hold voltage 76, and the voltage along common line 3 remains at a release voltage 70, leaving the modulators along common lines 2 and 3 in a relaxed position.

During the fourth line time 60d, the voltage on common line 1 returns to a high hold voltage 72, leaving the modulators along common line 1 in their respective addressed states. The voltage on common line 2 is decreased to a low address voltage 78. Because a high segment voltage 62 is applied along segment line 2, the pixel voltage across modulator (2,2) is below the lower end of the negative stability window of the modulator, causing the modulator (2,2) to actuate. Conversely, because a low segment voltage 64 is applied along segment lines 1 and 3, the modulators (2,1) and (2,3) remain in a relaxed position. The voltage on common line 3 increases to a high hold voltage 72, leaving the modulators along common line 3 in a relaxed state.

Finally, during the fifth line time 60e, the voltage on common line 1 remains at high hold voltage 72, and the voltage on common line 2 remains at a low hold voltage 76, leaving the modulators along common lines 1 and 2 in their respective addressed states. The voltage on common line 3 increases to a high address voltage 74 to address the modulators along common line 3. As a low segment voltage 64 is applied on segment lines 2 and 3, the modulators (3,2) and (3,3) actuate, while the high segment voltage 62 applied along segment line 1 causes modulator (3,1) to remain in a relaxed position. Thus, at the end of the fifth line time 60e, the 3×3 pixel array is in the state shown in FIG. 5A, and will remain in that state as long as the hold voltages are applied along the common lines, regardless of variations in the segment voltage which may occur when modulators along other common lines (not shown) are being addressed.

In the timing diagram of FIG. 5B, a given write procedure (i.e., line times 60a-60e) can include the use of either high hold and address voltages, or low hold and address voltages. Once the write procedure has been completed for a given common line (and the common voltage is set to the hold voltage having the same polarity as the actuation voltage), the pixel voltage remains within a given stability window, and does not pass through the relaxation window until a release voltage is applied on that common line. Furthermore, as each modulator is released as part of the write procedure prior to addressing the modulator, the actuation time of a modulator, rather than the release time, may determine the necessary line time. Specifically, in implementations in which the release time of a modulator is greater than the actuation time, the release voltage may be applied for longer than a single line time, as depicted in FIG. 5B. In some other implementations, voltages applied along common lines or segment lines may vary to account for variations in the actuation and release voltages of different modulators, such as modulators of different colors.

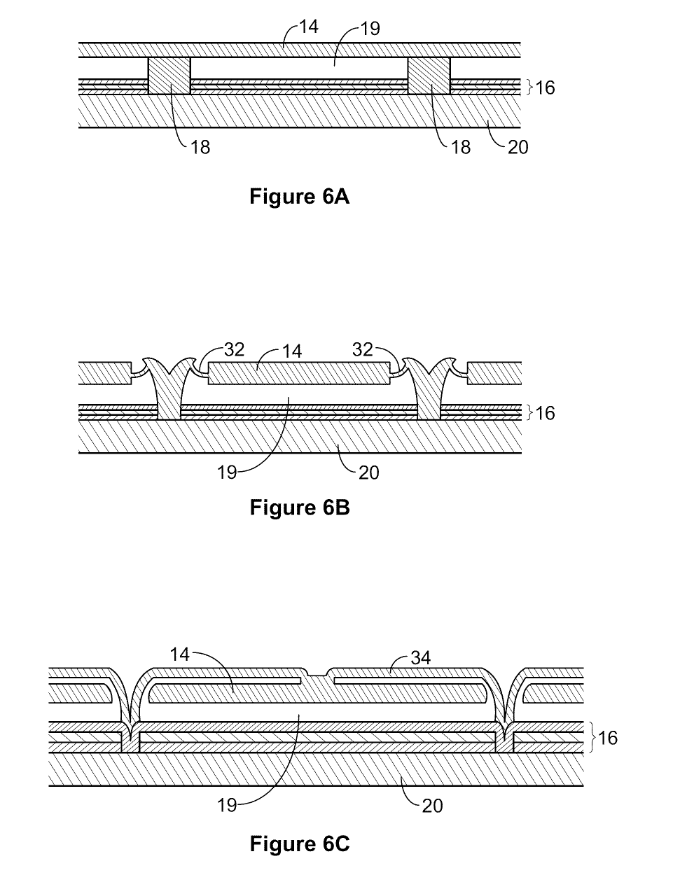

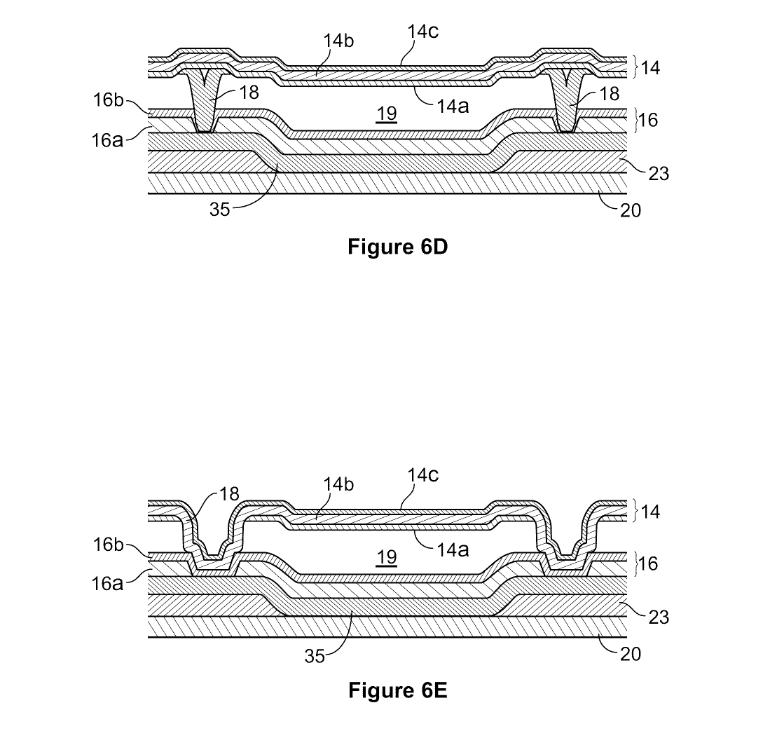

The details of the structure of interferometric modulators that operate in accordance with the principles set forth above may vary widely. For example, FIGS. 6A-6E show examples of cross-sections of varying implementations of interferometric modulators, including the movable reflective layer 14 and its supporting structures. FIG. 6A shows an example of a partial cross-section of the interferometric modulator display of FIG. 1, where a strip of metal material, i.e., the movable reflective layer 14 is deposited on supports 18 extending orthogonally from the substrate 20. In FIG. 6B, the movable reflective layer 14 of each IMOD is generally square or rectangular in shape and attached to supports at or near the corners, on tethers 32. In FIG. 6C, the movable reflective layer 14 is generally square or rectangular in shape and suspended from a deformable layer 34, which may include a flexible metal. The deformable layer 34 can connect, directly or indirectly, to the substrate 20 around the perimeter of the movable reflective layer 14. These connections are herein referred to as support posts. The implementation shown in FIG. 6C has additional benefits deriving from the decoupling of the optical functions of the movable reflective layer 14 from its mechanical functions, which are carried out by the deformable layer 34. This decoupling allows the structural design and materials used for the reflective layer 14 and those used for the deformable layer 34 to be optimized independently of one another.

FIG. 6D shows another example of an IMOD, where the movable reflective layer 14 includes a reflective sub-layer 14a. The movable reflective layer 14 rests on a support structure, such as support posts 18. The support posts 18 provide separation of the movable reflective layer 14 from the lower stationary electrode (i.e., part of the optical stack 16 in the illustrated IMOD) so that a gap 19 is formed between the movable reflective layer 14 and the optical stack 16, for example when the movable reflective layer 14 is in a relaxed position. The movable reflective layer 14 also can include a conductive layer 14c, which may be configured to serve as an electrode, and a support layer 14b. In this example, the conductive layer 14c is disposed on one side of the support layer 14b, distal from the substrate 20, and the reflective sub-layer 14a is disposed on the other side of the support layer 14b, proximal to the substrate 20. In some implementations, the reflective sub-layer 14a can be conductive and can be disposed between the support layer 14b and the optical stack 16. The support layer 14b can include one or more layers of a dielectric material, for example, silicon oxynitride (SiON) or silicon dioxide (SiO₂). In some implementations, the support layer 14b can be a stack of layers, such as, for example, a SiO₂/SiON/SiO₂ tri-layer stack. Either or both of the reflective sub-layer 14a and the conductive layer 14c can include, e.g., an aluminum (Al) alloy with about 0.5% copper (Cu), or another reflective metallic material. Employing conductive layers 14a, 14c above and below the dielectric support layer 14b can balance stresses and provide enhanced conduction. In some implementations, the reflective sub-layer 14a and the conductive layer 14c can be formed of different materials for a variety of design purposes, such as achieving specific stress profiles within the movable reflective layer 14.

As illustrated in FIG. 6D, some implementations also can include a black mask structure 23. The black mask structure 23 can be formed in optically inactive regions (e.g., between pixels or under posts 18) to absorb ambient or stray light. The black mask structure 23 also can improve the optical properties of a display device by inhibiting light from being reflected from or transmitted through inactive portions of the display, thereby increasing the contrast ratio. Additionally, the black mask structure 23 can be conductive and be configured to function as an electrical bussing layer. In some implementations, the row electrodes can be connected to the black mask structure 23 to reduce the resistance of the connected row electrode. The black mask structure 23 can be formed using a variety of methods, including deposition and patterning techniques. The black mask structure 23 can include one or more layers. For example, in some implementations, the black mask structure 23 includes a molybdenum-chromium (MoCr) layer that serves as an optical absorber, a layer, and an aluminum alloy that serves as a reflector and a bussing layer, with a thickness in the range of about 30-80 Å, 500-1000 Å, and 500-6000 Å, respectively. The one or more layers can be patterned using a variety of techniques, including photolithography and dry etching, including, for example, carbon tetrafluoride (CF₄) and/or oxygen (O₂) for the MoCr and SiO₂ layers and chlorine (Cl₂) and/or boron trichloride (BCl₃) for the aluminum alloy layer. In some implementations, the black mask 23 can be an etalon or interferometric stack structure. In such interferometric stack black mask structures 23, the conductive absorbers can be used to transmit or bus signals between lower, stationary electrodes in the optical stack 16 of each row or column. In some implementations, a spacer layer 35 can serve to generally electrically isolate the absorber layer 16a from the conductive layers in the black mask 23.

FIG. 6E shows another example of an IMOD, where the movable reflective layer 14 is self supporting. In contrast with FIG. 6D, the implementation of FIG. 6E does not include support posts 18. Instead, the movable reflective layer 14 contacts the underlying optical stack 16 at multiple locations, and the curvature of the movable reflective layer 14 provides sufficient support that the movable reflective layer 14 returns to the unactuated position of FIG. 6E when the voltage across the interferometric modulator is insufficient to cause actuation. The optical stack 16, which may contain a plurality of several different layers, is shown here for clarity including an optical absorber 16a, and a dielectric 16b. In some implementations, the optical absorber 16a may serve both as a fixed electrode and as a partially reflective layer.

In implementations such as those shown in FIGS. 6A-6E, the IMODs function as direct-view devices, in which images are viewed from the front side of the transparent substrate 20, i.e., the side opposite to that upon which the modulator is arranged. In these implementations, the back portions of the device (that is, any portion of the display device behind the movable reflective layer 14, including, for example, the deformable layer 34 illustrated in FIG. 6C) can be configured and operated upon without impacting or negatively affecting the image quality of the display device, because the reflective layer 14 optically shields those portions of the device. For example, in some implementations a bus structure (not illustrated) can be included behind the movable reflective layer 14 which provides the ability to separate the optical properties of the modulator from the electromechanical properties of the modulator, such as voltage addressing and the movements that result from such addressing. Additionally, the implementations of FIGS. 6A-6E can simplify processing, such as, e.g., patterning.

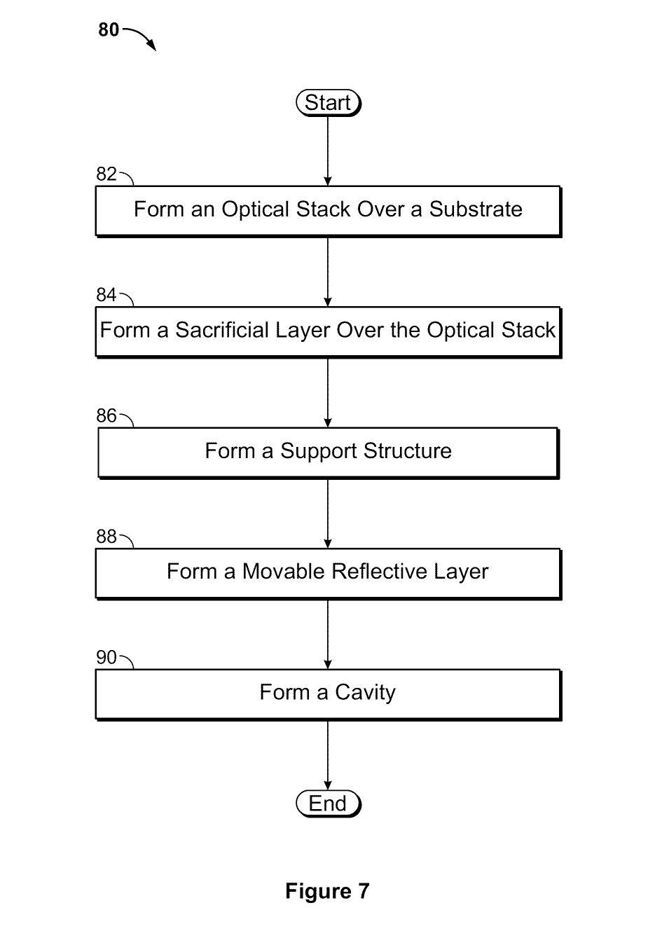

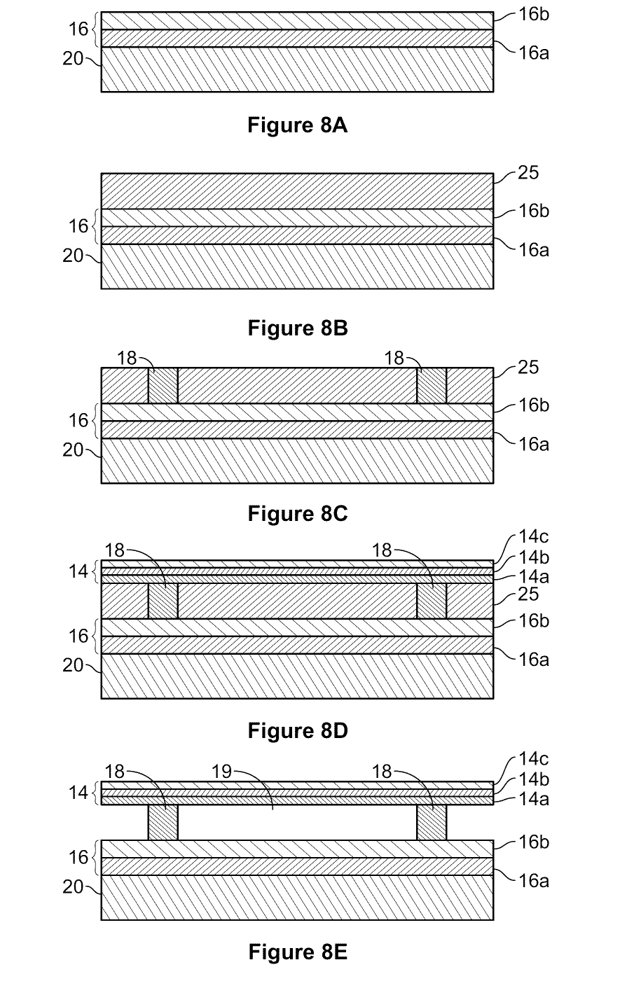

FIG. 7 shows an example of a flow diagram illustrating a manufacturing process 80 for an interferometric modulator, and FIGS. 8A-8E show examples of cross-sectional schematic illustrations of corresponding stages of such a manufacturing process 80. In some implementations, the manufacturing process 80 can be implemented to manufacture, e.g., interferometric modulators of the general type illustrated in FIGS. 1 and 6, in addition to other blocks not shown in FIG. 7. With reference to FIGS. 1, 6 and 7, the process 80 begins at block 82 with the formation of the optical stack 16 over the substrate 20. FIG. 8A illustrates such an optical stack 16 formed over the substrate 20. The substrate 20 may be a transparent substrate such as glass or plastic, it may be flexible or relatively stiff and unbending, and may have been subjected to prior preparation processes, e.g., cleaning, to facilitate efficient formation of the optical stack 16. As discussed above, the optical stack 16 can be electrically conductive, partially transparent and partially reflective and may be fabricated, for example, by depositing one or more layers having the desired properties onto the transparent substrate 20. In FIG. 8A, the optical stack 16 includes a multilayer structure having sub-layers 16a and 16b, although more or fewer sub-layers may be included in some other implementations. In some implementations, one of the sub-layers 16a, 16b can be configured with both optically absorptive and conductive properties, such as the combined conductor/absorber sub-layer 16a. Additionally, one or more of the sub-layers 16a, 16b can be patterned into parallel strips, and may form row electrodes in a display device. Such patterning can be performed by a masking and etching process or another suitable process known in the art. In some implementations, one of the sub-layers 16a, 16b can be an insulating or dielectric layer, such as sub-layer 16b that is deposited over one or more metal layers (e.g., one or more reflective and/or conductive layers). In addition, the optical stack 16 can be patterned into individual and parallel strips that form the rows of the display.

The process 80 continues at block 84 with the formation of a sacrificial layer 25 over the optical stack 16. The sacrificial layer 25 is later removed (e.g., at block 90) to form the cavity 19 and thus the sacrificial layer 25 is not shown in the resulting interferometric modulators 12 illustrated in FIG. 1. FIG. 8B illustrates a partially fabricated device including a sacrificial layer 25 formed over the optical stack 16. The formation of the sacrificial layer 25 over the optical stack 16 may include deposition of a xenon difluoride (XeF₂)-etchable material such as molybdenum (Mo) or amorphous silicon (a-Si), in a thickness selected to provide, after subsequent removal, a gap or cavity 19 (see also FIGS. 1 and 8E) having a desired design size. Deposition of the sacrificial material may be carried out using deposition techniques such as physical vapor deposition (PVD, e.g., sputtering), plasma-enhanced chemical vapor deposition (PECVD), thermal chemical vapor deposition (thermal CVD), or spin-coating.

The process 80 continues at block 86 with the formation of a support structure e.g., a post 18 as illustrated in FIGS. 1, 6 and 8C. The formation of the post 18 may include patterning the sacrificial layer 25 to form a support structure aperture, then depositing a material (e.g., a polymer or an inorganic material, e.g., silicon oxide) into the aperture to form the post 18, using a deposition method such as PVD, PECVD, thermal CVD, or spin-coating. In some implementations, the support structure aperture formed in the sacrificial layer can extend through both the sacrificial layer 25 and the optical stack 16 to the underlying substrate 20, so that the lower end of the post 18 contacts the substrate 20 as illustrated in FIG. 6A. Alternatively, as depicted in FIG. 8C, the aperture formed in the sacrificial layer 25 can extend through the sacrificial layer 25, but not through the optical stack 16. For example, FIG. 8E illustrates the lower ends of the support posts 18 in contact with an upper surface of the optical stack 16. The post 18, or other support structures, may be formed by depositing a layer of support structure material over the sacrificial layer 25 and patterning portions of the support structure material located away from apertures in the sacrificial layer 25. The support structures may be located within the apertures, as illustrated in FIG. 8C, but also can, at least partially, extend over a portion of the sacrificial layer 25. As noted above, the patterning of the sacrificial layer 25 and/or the support posts 18 can be performed by a patterning and etching process, but also may be performed by alternative etching methods.

The process 80 continues at block 88 with the formation of a movable reflective layer or membrane such as the movable reflective layer 14 illustrated in FIGS. 1, 6 and 8D. The movable reflective layer 14 may be formed by employing one or more deposition steps, e.g., reflective layer (e.g., aluminum, aluminum alloy) deposition, along with one or more patterning, masking, and/or etching steps. The movable reflective layer 14 can be electrically conductive, and referred to as an electrically conductive layer. In some implementations, the movable reflective layer 14 may include a plurality of sub-layers 14a, 14b, 14c as shown in FIG. 8D. In some implementations, one or more of the sub-layers, such as sub-layers 14a, 14c, may include highly reflective sub-layers selected for their optical properties, and another sub-layer 14b may include a mechanical sub-layer selected for its mechanical properties. Since the sacrificial layer 25 is still present in the partially fabricated interferometric modulator formed at block 88, the movable reflective layer 14 is typically not movable at this stage. A partially fabricated IMOD that contains a sacrificial layer 25 may also be referred to herein as an “unreleased” IMOD. As described above in connection with FIG. 1, the movable reflective layer 14 can be patterned into individual and parallel strips that form the columns of the display.

The process 80 continues at block 90 with the formation of a cavity, e.g., cavity 19 as illustrated in FIGS. 1, 6 and 8E. The cavity 19 may be formed by exposing the sacrificial material 25 (deposited at block 84) to an etchant. For example, an etchable sacrificial material such as Mo or amorphous Si may be removed by dry chemical etching, e.g., by exposing the sacrificial layer 25 to a gaseous or vaporous etchant, such as vapors derived from solid XeF₂ for a period of time that is effective to remove the desired amount of material, typically selectively removed relative to the structures surrounding the cavity 19. Other etching methods, e.g. wet etching and/or plasma etching, also may be used. Since the sacrificial layer 25 is removed during block 90, the movable reflective layer 14 is typically movable after this stage. After removal of the sacrificial material 25, the resulting fully or partially fabricated IMOD may be referred to herein as a “released” IMOD.

Display devices may also be configured to include display elements having three electrodes. Such a device may generally be referred to as a tri-state device. In these devices, a selected voltage is applied to two fixed electrodes and to a movable middle electrode that is between the two fixed electrodes. Based on the potential difference between the electrodes, the movable middle electrode is positioned in one of three positions relative to the two fixed electrodes.

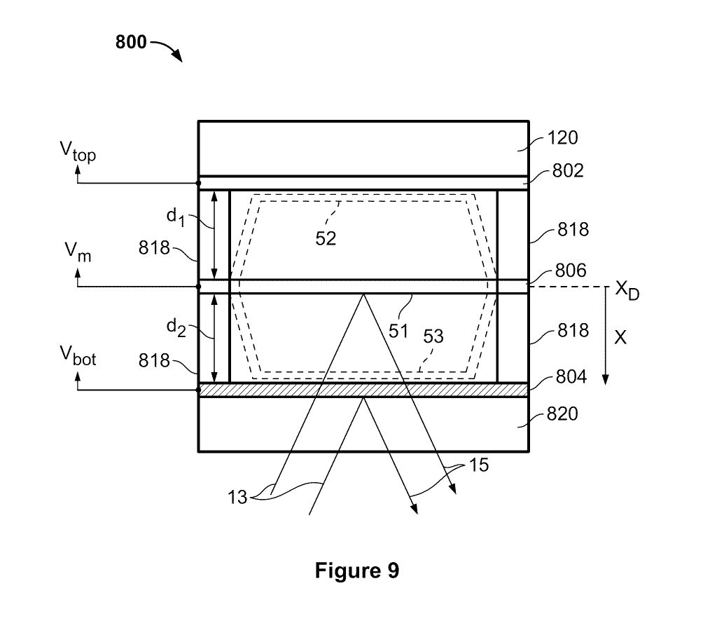

FIG. 9 is a cross-section of an implementation of a display element 800 having two fixed layers and a movable third layer. Specifically, FIG. 9 shows an implementation of a tri-state interferometric modulator having a substantially fixed first layer 802, a substantially fixed second layer 804, and a movable third layer 806 positioned between the fixed first and second layers 802 and 804. Each of the layers 802, 804, and 806 may include, or be coupled to, an electrode or other conductive material. For example, the fixed first layer 802 and the fixed second layer 804 may include a plate made of metal. The fixed first layer 802 and fixed second layer 804 may be referred to herein as fixed conductive layers, while the movable third layer 806 may be referred to herein as a movable conductive layer. Each of the layers 802, 804, and 806 may be stiffened using a stiffening layer formed on or deposited on the respective layer. In one implementation, the stiffening layer includes a dielectric. The stiffening layer may be used to keep the layer to which it is attached rigid and substantially flat. Some implementations of the display element 800 may be referred to as a three-terminal or tri-state interferometric modulator. Note that in some alternative implementations, the first layer 802 and the second layer 804 may not be fixed, and they may move or bend in response to certain combinations of voltages applied across the display element 800.

The three layers 802, 804, and 806 are electrically insulated by insulating posts 818. The movable third layer 806 is suspended from the insulating posts 810. The movable third layer 806 is configured to move such that the movable third layer 806 may be displaced in a generally upward direction toward the fixed first layer 802, or may be displaced in a generally downward direction toward to the fixed second layer 804. In some implementations, the fixed first layer 802 may also be referred to as the top layer or top electrode. In some implementations, the fixed second layer 804 may also be referred to as the bottom layer or bottom electrode. The display element 800 may be supported by a substrate 820.

In FIG. 9, the movable third layer 806 is illustrated as being in a middle position with the solid lines (e.g., position S1). As illustrated in FIG. 9, d₂ corresponds to the distance between the fixed second layer 804 and the movable third layer 806 in the middle position S1, while d₁ corresponds to the distance between the fixed first layer 802 and the movable third layer 806 in the middle position S1. The position of the movable third layer 806 from the middle position between the fixed first layer 802 and fixed second layer 806 (e.g., d₁=d₂) may be indicated by a value x as illustrated in FIG. 9, where a positive value of x corresponds to a position closer to the fixed second layer 804 and a negative value of x corresponds to a distance that is farther from the fixed second layer 804.

As illustrated in FIG. 9, a voltage difference may be applied between the fixed first layer 802 and the fixed second layer 804. In the implementation of FIG. 9, a variable voltage Vₘ is applied to the movable third layer 806, a variable voltage Vₜₒₚ is applied to fixed first layer 802, and a variable voltage V_{bot} may be applied to the fixed second layer 804. By applying a variable voltage to the fixed first layer 802, the fixed second layer 804, and the movable third layer 806, the movable third layer 806 can be positioned at a desired location (e.g., S1, S2, and S3 as illustrated), thereby producing a desired optical response. The voltages applied to the fixed first 802, the fixed second layers 804, and the movable third layer 806 can vary widely depending on the materials and construction of the device, and in many implementations may be in the range of about 5-20 volts.

The electro-static pull acting on the movable third layer may be described with reference to Equation 1 below.

$$\frac{A {ɛ}_{0}}{2} [ \frac{{( {V}_{Top} - {V}_{M} )}^{2}}{{( {d}_{1} - x )}^{2}} - \frac{{( {V}_{Bot} - {V}_{M} )}^{2}}{{( {d}_{2} + x )}^{2}} ] = K \cdot x \qquad Eq . ( 1 )$$

where A is the area of the movable third layer 806, ∈₀ is the permittivity constant, Vₜₒₚ is the variable voltage applied to the fixed first layer 802, Vₘ is the variable voltage applied to the movable third layer 806, V_{bot} is the variable voltage applied to the fixed second layer 804, d₁ corresponds to the distance between the fixed first layer 802 and the movable third layer 806 when the movable third layer is in the un-driven (no voltages applied) position, d₂ corresponds to the distance between the fixed second layer 804 and the movable third layer 806 when the movable third layer 806 is in the middle position, and x is the displacement of the movable third layer 806 away from the fixed second layer 804.

The movable third layer 806 may include a mirror to reflect light entering the interferometric modulator through substrate 820. The mirror may include a metal material. The fixed second layer 804 may include a partially absorbing material such that the fixed second layer 804 acts as an absorbing layer. When light reflected from the movable third layer 806 is viewed from the side of the substrate 820, the viewer may perceive the reflected light as a certain color. By adjusting the position of the movable third layer 806 to one of the positions S1, S2, and S3 as illustrated in FIG. 9, certain wavelengths of light may be selectively reflected and/or absorbed.

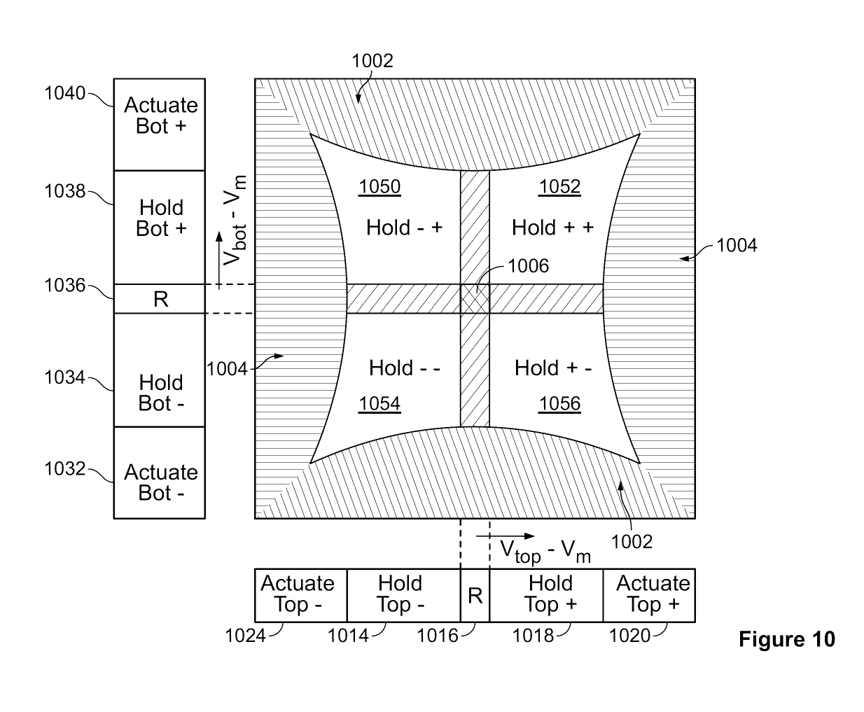

FIG. 10 shows an example of a diagram illustrating a movable middle layer 806 position versus applied voltage for the interferometric modulator of FIG. 9. For a tri-state display element 800, the row/column (i.e., common/segment) write procedure may take advantage of a hysteresis property of these devices as illustrated in FIG. 10. As illustrated, the hysteresis property may be similar to the hysteresis property of FIG. 3 for each half of the tri-state display element 800. FIG. 10 illustrates a two-dimensional view of the overlapping hysteresis windows for voltage differences of a top portion and a bottom portion of the display element 800. For example, as shown in FIG. 10, independently considered positive and negative hysteresis windows of the display element 800 for a top portion is illustrated along the horizontal axis according to top portion states 1010. The independently considered positive and negative hysteresis windows of the display element for a bottom portion is illustrated along the vertical axis according to the bottom portion states 1030. As illustrated, a large negative voltage difference (Top −) between the top layer (e.g., fixed first layer 802) and the middle layer (e.g., movable middle layer 806) produces an actuated state of the display element 800 towards the top (e.g., display element position S2). In some implementations, the large negative voltage difference can range from −10V to −20V. Similarly, a large positive voltage difference (Top +) between the top layer (e.g., fixed first layer 802) and the middle layer (e.g., movable middle layer 806) produces an actuated state of the display element 800 towards the top (e.g., display element position S2).). In some implementations, the large positive voltage difference can range from 10V to 20V. A voltage difference between the top layer and the movable middle layer that corresponds to a hold state of the display element 800 within a hysteresis window of the top portion of the display element is shown as top portion hold regions 1014 and 1018. A voltage difference producing a release state for a top half of the display element 800 is shown as release state 1016, which is illustrated as a vertical strip of voltages in the hysteresis curve of FIG. 10.

Similarly, an actuation voltage for a bottom portion of a display element 800 corresponds to voltage differences having a value of Bot − and Bot +, and is illustrated as bottom portion actuated states 1032 and 1040 respectively. A hold state for the bottom portion corresponds to hold windows 1034 and 1038. A release state for the bottom portion corresponds to a release window 1036, which is illustrated as horizontal strip of voltage differences in the hysteresis curve of FIG. 10. The overlapping hysteresis curves describe the behavior of the display element 800 for voltages applied to top layer (e.g., the first layer 802), the movable middle layer 806, and the bottom layer (e.g., the second layer 804). As shown, the overlapping hysteresis curves result in four different stability windows 1050, 1052, 1054, and 1056. The curved shapes of the stability windows with their pointed corners is a result of the interaction of the voltages applied to the top portion and the bottom portion, and the corresponding effect on the behavior of the display element 800. The height, width, and shape of the stability windows may be dependent on the ratio of the height of each gap of the display element 800 (e.g., distance d₁ and d₂) and is not limited to the square shaped example shown in FIG. 10 which is applicable to equal values for d₁ and d₂.

A release state (e.g., display element position S1) of the display element 800 corresponds to the overlapping area of the release windows for the top portion and the bottom portion of the display element as illustrated by relaxed window 1006. Further, a top actuated position (e.g., display element position S2) corresponds to top actuation windows 1004, while a bottom actuation position (e.g., display element position S3) corresponds to bottom actuation windows 1002.

Tri-state display elements may be placed in any of three desired positions S1, S2 or S3 by placing the appropriate voltage across the three layers in accordance with the two-dimensional hysteresis curve of FIG. 10. Once in the desired state, any set of voltages within regions 1050, 1052, 1054, and 1056 may be applied to maintain the display element in the state the element was placed.

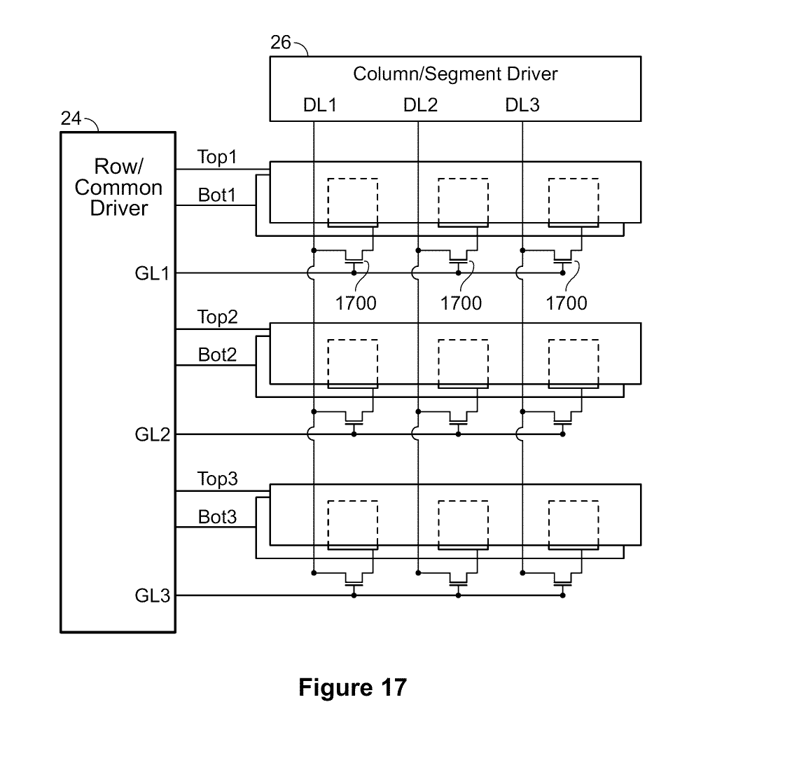

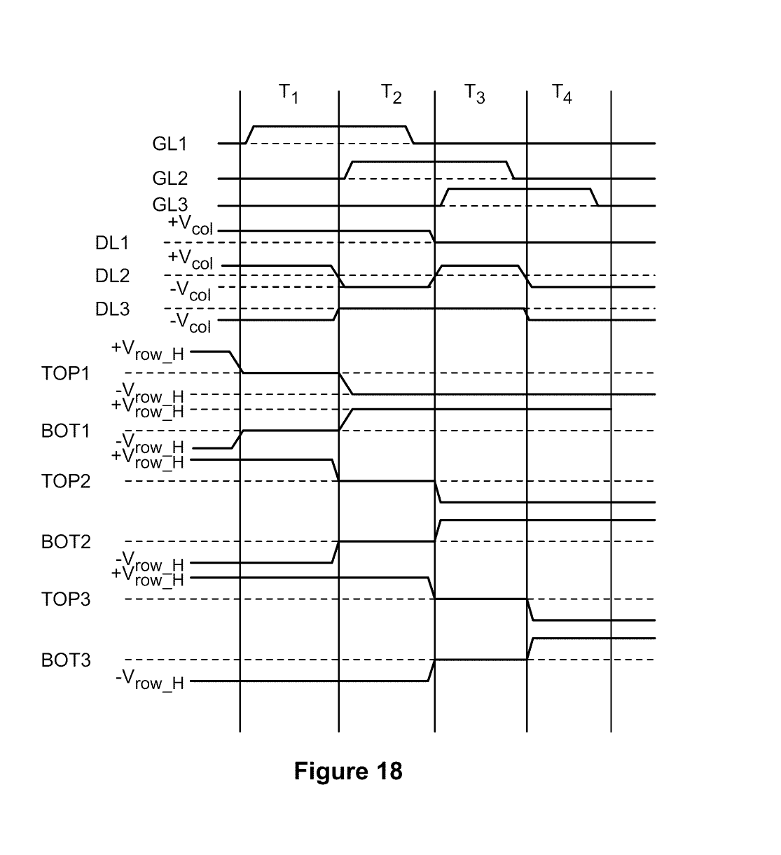

An array of display elements 800 may be addressed with an “active matrix” drive scheme, where a transistor or other isolating circuitry is associated with each display element 800. In an “active matrix” drive scheme, fixed voltages may be applied to the fixed first layer 802 and the fixed second layer 804. A variable voltage may be applied to the movable third layer 806 through operation of the isolating circuitry (e.g., transistor switch) associated with the display element 800. For example, a transistor switch output may couple to the movable third layer 806. An output of a first driver may be connected to a gate terminal of the transistor switch through a gate line, and may be provided as a signal to a gate terminal of the transistor switch connected to the movable third layer 806. A second driver may be configured to provide a data signal along a segment line to a first terminal of the transistor switch. In this way, the transistor switch is configured as a switch for providing a voltage to the middle electrode 806 based on an output of both the first and second drivers. An example of an active matrix drive scheme will be described in greater detail below with reference to FIGS. 17 and 18 below.

In some implementations, an array of display elements 800 may be addressed using a “passive matrix” drive scheme. The “passive matrix” drive scheme does not include isolating circuitry (e.g., transistor switches) which are connected to each of the display elements 800 as discussed above with reference to the “active matrix” drive scheme. Rather, in a “passive matrix” drive scheme, a plurality of common lines and a plurality of segment lines are connected directly to each electrode of the display element 800.

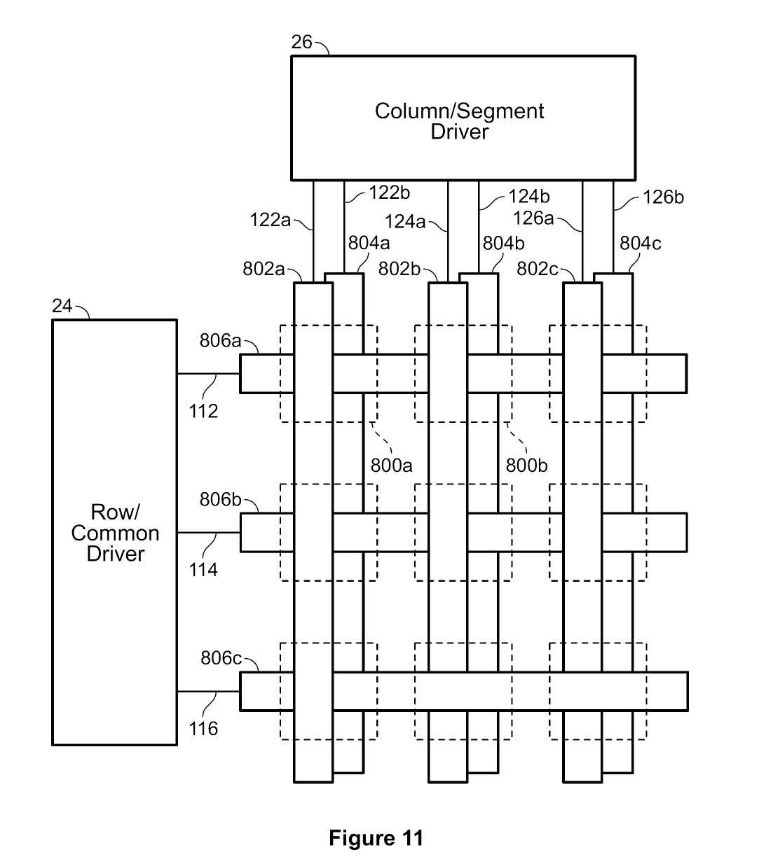

FIG. 11 illustrates an example of an array of tri-state display elements that can be driven with a passive matrix drive scheme having two segment lines and one common line according to some implementations. As illustrated in FIG. 11, display elements are formed at the intersections of the row electrodes and column electrodes arranged in an array. For example, a display element 800A is formed at the intersection of column electrodes 802A, 802B and row electrode 806A, while a display element 800B is formed at the intersection of column electrodes 802B, 804B and row electrode 806B. The array of FIG. 10 includes a 3×3 array of display elements 800. A person having ordinary skill in the art will recognize that the size of the array is not limited thereto.

As illustrated in FIG. 11, the column electrodes 802A and 802B correspond to the fixed first layer 802 (e.g., top electrode) and fixed second layer 804 (e.g., bottom electrode) as described above with reference to FIG. 9, while the row electrode 806A corresponds to the movable third layer 806 (e.g., middle electrode) of the display element 800. A tri-state passive matrix driven array may include a row/common driver 24 configured to apply a voltage to the row electrodes 806A, 806B, and 806C through a plurality of common lines (e.g., common lines 112, 114, and 116). A column/segment driver 26 may be configured to apply a voltage to the column electrodes 802A, 804A, 802B, 804B, 802C, and 804C. through a plurality of segment lines (e.g. first segment lines 122A, 124A, 126A and second segment lines 122B, 124B, 126B). As illustrated in FIG. 11, the array includes one common line and two segment lines for each display element 800. Each of the electrodes of each of the display elements 800 is directly connected to the driver lines in the tri-state passive matrix drive scheme.

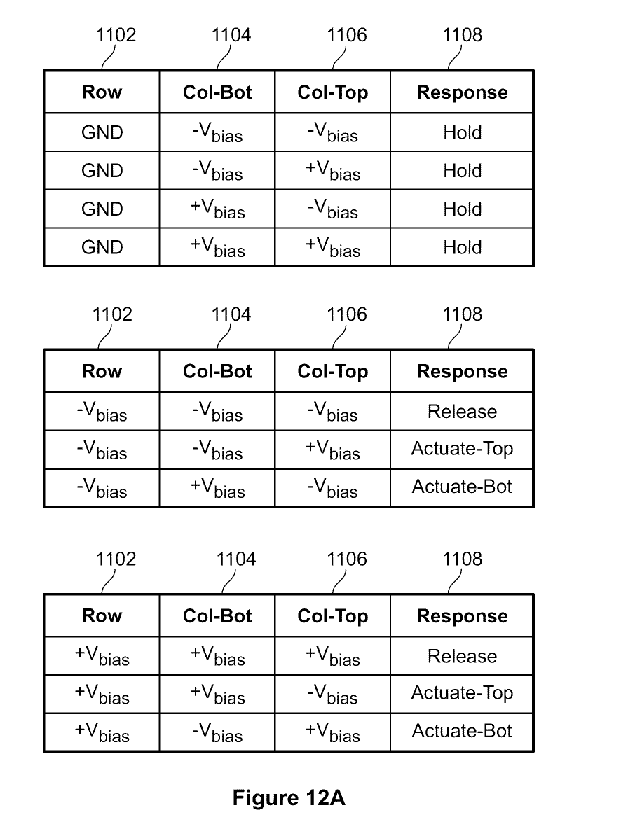

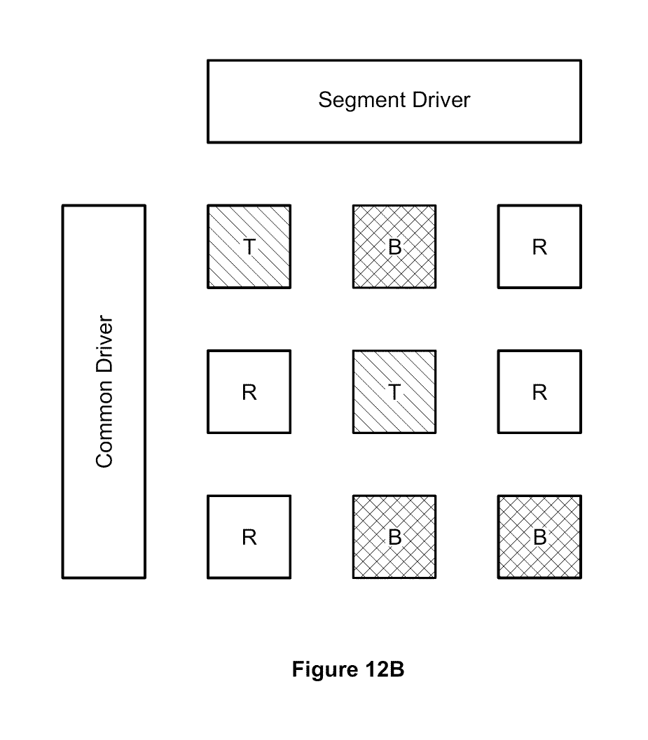

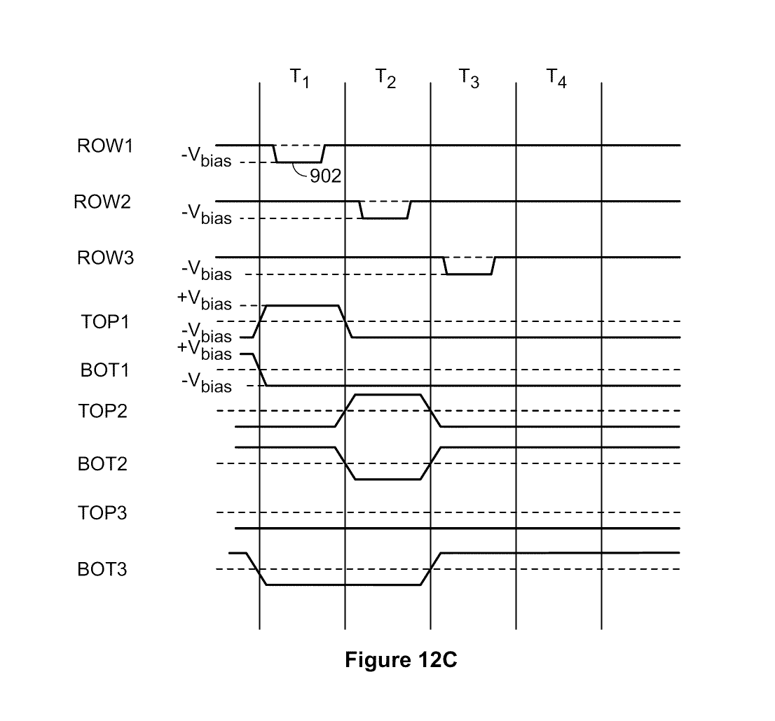

FIG. 12A is an example of voltages applied to the common lines and segment lines in a passive matrix drive scheme according to some implementations. As illustrated in FIG. 12A, the voltage applied to the common lines (e.g., common lines 112, 114, and 116 of FIG. 11) and along each row electrode are illustrated in column 1202. The voltages applied to the segment lines (e.g., second segment lines 122B, 124B, and 126B of FIG. 11) connected to the bottom electrode (e.g., column electrodes 804A, 804B, and 804C of FIG. 11) are illustrated in column 1204. The voltages applied to the segment lines (e.g., first segment lines 122A, 124A, and 126A of FIG. 11) connected to the top electrode (e.g., column electrodes 802A, 802B, and 802C of FIG. 10) are illustrated in column 1206. The response of a display element 800 having the voltages applied as illustrated in the table is shown in column 1208.

As shown in FIG. 12A, the row electrodes may be transitioned between voltages having values of +V_{bias}, −V_{bias}, and ground (GND), while the column electrodes may be transitioned between voltages having values of +V_{bias} and −V_{bias}. The value of V_{bias} may range from about 4V to 20V in various implementations, and may be different for the top and bottom electrodes if the gap sizes are different. With returned reference to FIG. 3, and FIG. 10, the voltage level V_{bias} may correspond to the center of the hold or stability window corresponding to each half of the display element 800. For example, a voltage difference V_{bias} between the movable third layer 806 and the fixed first layer 802 may correspond to the center of the stability window as illustrated in FIG. 3 for a top half of the display element 800. Similarly, a voltage difference V_{bias} between the movable third layer 806 and the fixed first layer 802 may correspond to the center of the stability window as illustrated in FIG. 3 for a bottom half of the display element 800. As shown in FIG. 12A, the application of a ground voltage (GND) to the middle electrode (e.g., the movable third layer 806) results in a hold response for the display element 800 regardless of the voltages (e.g., +/−V_{bias}) applied to the column electrodes (e.g., fixed first layer 802 and fixed second layer 804). For example, when writing data to a first row of display elements 800, a second row of display elements 800 may be supplied with a (GND) voltage such that the display elements 800 along the second row of the array will be maintained in their current state.

To place a display element 800 in a released state, or a position S1 at which the movable third layer 806 is substantially centered between the fixed first layer 802 and the fixed second layer 804, a voltage −V_{bias} may be applied to each of the electrodes such that a voltage difference between the movable third layer 806 and each of the fixed first layer 802 and the fixed second layer 804 is substantially zero volts. The voltage difference of zero volts corresponds to the relaxed or released window 1006 of the hysteresis curve as illustrated in FIG. 10 for each half of the display element 800.

To move the movable third layer 806 to an actuated top position S2 relative to the fixed first layer 802 (top electrode), a voltage −V_{bias} may be applied to the middle electrode (e.g., movable third layer 806) while a voltage −V_{bias} is applied to a bottom electrode (e.g., through second segment electrodes 122B, 124B, and/or 126B of FIG. 10) and a voltage +V_{bias} is applied to a top electrode (e.g., through first segment electrodes 122A, 124A, and/or 126A of FIG. 11). To move the movable third layer 806 to an actuated bottom position S3 relative to the fixed second layer 804 (bottom electrode), a voltage −V_{bias} may be applied to the row electrode (e.g., movable third layer 806) while a voltage +V_{bias} is applied to a bottom electrode (e.g., second column electrodes 122B, 124B, and/or 126B of FIG. 11) and a voltage −V_{bias} is applied to a top electrode (e.g., a first column electrodes 122A, 124A, and/or 126A of FIG. 11). Alternatively, the middle electrodes may be transitioned to +V_{bias}, and the configuration of the positive/negative voltages for the column electrodes would be reversed for the same display element response as shown in FIG. 12A.

FIG. 12B illustrates a data pattern written to an array of tri-state display elements. This data pattern is used as an example for the timing diagrams presented below. In this example, the first element of the first row and the second element of the second row are actuated to the top position S2. The second element of the first row and the second and third elements of the third row are actuated to the bottom position S3. The remaining elements of the 3×3 array of FIG. 12B are in the central released position S1.

FIG. 12C illustrates an example waveform for driving a display element according to the voltage levels of FIG. 12A to write the data pattern of FIG. 12B. The waveforms illustrated in FIG. 12C will be described in connection with display array of FIG. 11. A person having ordinary skill in the art will recognize that the waveforms described with respect to FIG. 12C and similar waveforms may be applied to any number of display elements 800 arranged in an array. As illustrated in FIG. 12C, the voltage applied on each of the row electrodes is initially zero volts. Each of the column electrodes are at either +V_{bias} or −V_{bias}. This is a hold state for all the elements, which will be stable in whatever their current position is. During a first time period T₁, the segment driver 26 applies data signals to the six column electrodes, and the row 1 common electrode 112 is strobed with a write pulse 902 of −V_{bias}. As described above with respect to FIG. 12A, to actuate the first element of the first row to the top, the top segment electrode 122A is set to +V_{bias} and the bottom electrode 122B is set to −V_{bias}. This will cause the first display element 800A of the first row to be actuated to the top electrode during the common line write pulse 902 on electrode 112 during time T1. Similarly, the top electrode 124A and bottom electrode 124B of the second display element 800B of the first row are set to −V_{bias} and +V_{bias} respectively prior to the write pulse 902 of electrode 112. This causes the second display element 800B of the first row to be actuated to the bottom electrode. For the third display element of the first row, both the top electrode and the bottom electrode are set to −V_{bias} prior to the row pulse 902. This sets the state of the third element to the released state S1 during the row pulse 902 on the electrode 112. This process is sequentially repeated for the second and third rows with row pulses 904 and 906 applied to electrodes 114 and 116 respectively, where the voltages applied to the segment electrodes are suitable to cause release, top actuation, or bottom actuation as described above with respect to the first row. Following completion of writing the desired data pattern to the array, the voltage on all row electrodes 112, 114, and 116 is zero volts, and the voltage on each segment electrode is either −V_{bias} or +V_{bias}, such that each display element is in a hold state and the data pattern written is maintained. Although the waveforms of FIG. 12C are illustrated with a negative voltage pulse on the each row electrode, a positive row pulse could be used, wherein writing the same data would be accomplished using the opposite polarity segment voltages in each time period.

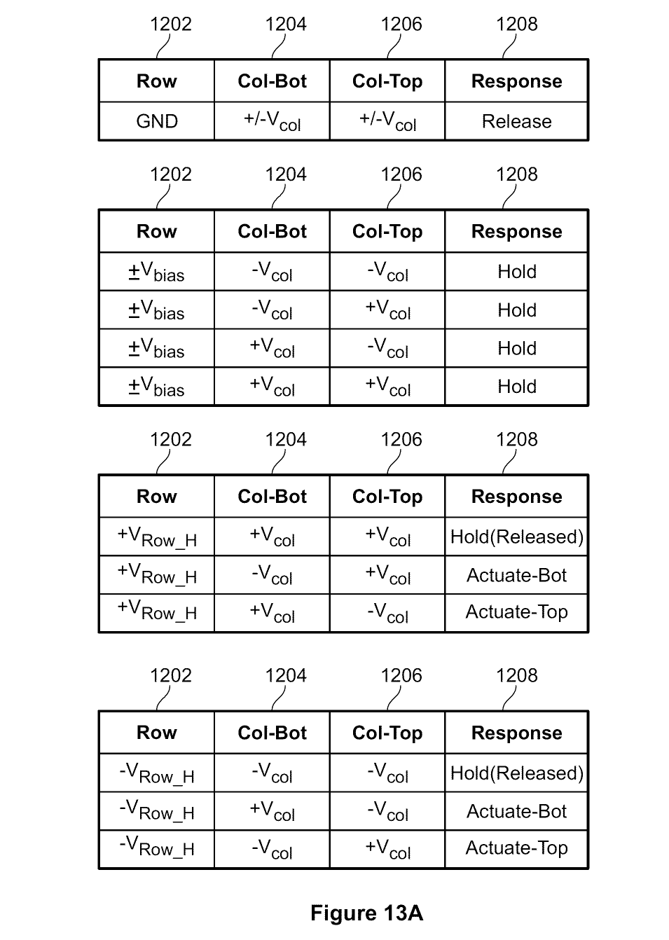

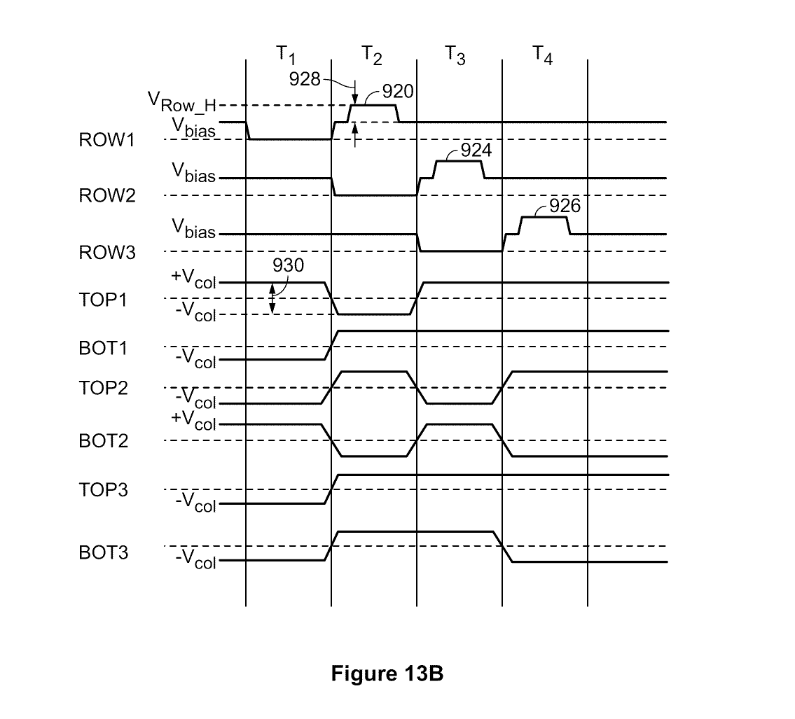

FIG. 13A is an example of voltages applied to the common lines and segment lines in a passive matrix drive scheme according to some implementations. As illustrated in FIG. 13A, the voltage applied to the common lines (e.g., common lines 112, 114, and 116 of FIG. 11) and along each row electrode are illustrated in column 1302. The voltages applied to the segment lines (e.g., segment lines 122B, 124B, and 126B of FIG. 11) connected to the bottom electrode (e.g., column electrodes 804A, 804B, and 804C of FIG. 11) are illustrated in column 1304. The voltages applied to the segment lines (e.g., segment lines 122A, 124A, and 126A of FIG. 11) connected to the top electrode (e.g., column electrodes 802A, 802B, and 802C of FIG. 11) are illustrated in column 1306. The response of a display element 800 having the voltages applied as illustrated in the table is shown in column 1308.

As shown in FIG. 13A, the row electrodes may be transitioned between voltages having values of +V_{Row}_{_{—}}_{H}, +V_{bias}, ground (GND), −V_{bias}, and −V_{Row}_{_{—}}_{H}, while the column electrodes may be transitioned between voltages having values of +V_{col} and −V_{col}. In the implementation of FIG. 13A, the magnitude of a write voltage V_{Row}_{_{—}}_{H} may be equal to (V_{bias}+ΔV) where ΔV is equal to half of the stability window width as illustrated in FIG. 3. Further, the magnitude of the column voltage V_{col} may be equal to a value of ΔV/2. These voltages values may be used to write data to rows of display elements 800 in the array while maintaining a current state of other rows of display elements 800 in the array during the write process.

As discussed above, and with returned reference to FIGS. 3 and 10, the voltage level V_{bias} may correspond to the center of the hold or stability window corresponding to each half the display element 800. For example, a voltage difference V_{bias} between the movable third layer 806 and the fixed first layer 802 may correspond to the center of the stability window as illustrated in FIG. 3 for a top half of the display element 800. Similarly, a voltage difference V_{bias} between the movable third layer 806 and the fixed first layer 802 may correspond to the center of the stability window as illustrated in FIG. 3 for a bottom half of the display element 800. As shown in FIG. 13A, the application of a bias voltage (+/−V_{bias}) to the row electrode (e.g., the movable third layer 806) results in a hold response for the display element 800 regardless of the voltage (e.g., +/−V_{col}) applied to the column electrodes (e.g., fixed first layer 802 and fixed second layer 804) since the magnitude of V_{col} is less than ΔV. That is, ±V_{bias}±V_{col} corresponds to a potential difference across each half of the tri-state display element that is within one of the stability windows 1052, 1054 as illustrated in FIG. 10.

Therefore, to maintain a current position of a first row of display element 800, when writing data to a second row of display elements 800, the first row of display elements 800 may be supplied with a bias voltage having a value of +/−V_{bias} such that the display elements 800 along the first row will be maintained in their current state.

To place a display element 800 in a released state, or a position S1 at which the movable third layer 806 is substantially centered between the fixed first layer 802 and the fixed second layer 804, a ground voltage (GND) may be applied to the row electrode. Application of the ground voltage to the middle electrode releases the display element 800 since the magnitude of the column voltage V_{col} has a value such that a potential difference across the movable third layer 806 and either of the fixed first layer 802 and fixed second layer 804 is within the relaxed window 1006 as illustrated in FIG. 10.

To move the movable third layer 806 to an actuated top position S2 relative to the fixed first layer 802 (top electrode), a write voltage +V_{Row}_{_{—}}_{H} may be applied to the row electrode (e.g., movable third layer 806) while a column voltage +V_{col} is applied to a bottom electrode (e.g., through second segment lines 122B, 124B, and/or 126B of FIG. 10) and a column voltage −V_{col} is applied to a top electrode (e.g., through first segment lines 122A, 124A, and/or 126A of FIG. 11). To move the movable third layer 806 to an actuated bottom position S3 relative to the fixed second layer 804 (bottom electrode), a write voltage +V_{Row}_{_{—}}_{H} may be applied to the row electrode (e.g., movable third layer 806) while a column voltage −V_{col} is applied to a bottom electrode (e.g., through second segment lines 122B, 124B, and/or 126B of FIG. 11) and a column voltage +V_{col} is applied to a top electrode (e.g., through first segment lines 122A, 124A, and/or 126A of FIG. 11). Alternatively, the row electrodes may be transitioned to a write voltage −V_{Row}_{_{—}}_{H}, and the configuration of the positive/negative voltages for the column electrodes would be reversed for the same display element response as shown in FIG. 13A.

Further, as illustrated in FIG. 13A, a display element in a released state may be maintained in a released position by application of a positive write voltage +V_{Row H} to the row electrode in combination with a positive column voltage +V_{col} to each of the column electrodes, or by application of the negative write voltage −V_{Row}_{_{—}}_{H} to the row electrode in combination with a negative column voltage −V_{col} to each of the column electrodes

FIG. 13B illustrates an example waveform for driving an array of display elements according to the voltage levels of FIG. 13A to write the data pattern of FIG. 12B. The waveforms illustrated in FIG. 13B will be described in connection with display array of FIG. 11. A person having ordinary skill in the art will recognize that the waveforms described with respect to FIG. 13B and similar waveforms may be applied to any number of display elements arranged in an array. As illustrated in FIG. 13B, the voltage applied on each of the row electrodes is initially +V_{bias}. Each of the column electrodes are at either +V_{cols} or −V_{col}. The difference in voltage between the two different data values +V_{col} and −V_{col} is denoted 930 in FIG. 13B, and may be referred to as the data pulse height or segment swing value. This combination of voltages on the row and column electrodes is a hold state for all the elements, which will be stable in whatever their current position is. During a first time period T₁, common electrode 112 is brought to zero volts. This releases all the display elements along the first row. In a second time period T2, the segment driver 26 applies data signals to the six column electrodes, and the row 1 common electrode 112 is strobed with a write pulse 920 of V_{Row}_{_{—}}_{H}, which as described above may be V_{bias}+ΔV. This value ΔV is denoted 928 in FIG. 13B and may be referred to as the scan pulse height. As described above with respect to FIG. 13A, to actuate the first element of the first row to the top, the top segment electrode 122A is set to −V_{col} and the bottom electrode 122B is set to +V_{col}. This will cause the first display element 800A of the first row to be actuated to the top electrode during the common line write pulse 920 on electrode 112 during time T2. Similarly, the top electrode 124A and bottom electrode 124B of the second display element 800B of the first row are set to +V_{col} and −V_{col} respectively prior to the write pulse 920 of electrode 112. This causes the second display element 800B of the first row to be actuated to the bottom electrode. For the third display element of the first row, both the top electrode and the bottom electrode are set to −V_{col} prior to the row pulse 920. This maintains the released state of the third element (released during time period T1) during the write pulse 920 on the electrode 112. Also during time period T2, the row electrode 114 is transitioned to zero volts, releasing the display elements of the second row in preparation for writing data to the second row. This process is sequentially repeated for the second and third rows with row pulses 924 and 926 applied to electrodes 114 and 116 respectively, where the voltages applied to the segment electrodes are suitable to cause top actuation, bottom actuation, or maintain a released state as described above with respect to the first row. Following completion of writing the desired data pattern to the array, the voltage on all row electrodes 112, 114, and 116 is +V_{bias}, and the voltage on each segment electrode is either −V_{col} or +V_{col}, such that each display element is in a hold state and the data pattern written is maintained. Although the waveforms of FIG. 3B are illustrated with a positive voltage pulse on each row electrode, a negative polarity row pulse could be used (such as is shown in FIG. 5B for a two state display element), wherein writing the same data would be accomplished using the opposite polarity segment voltages in each time period.

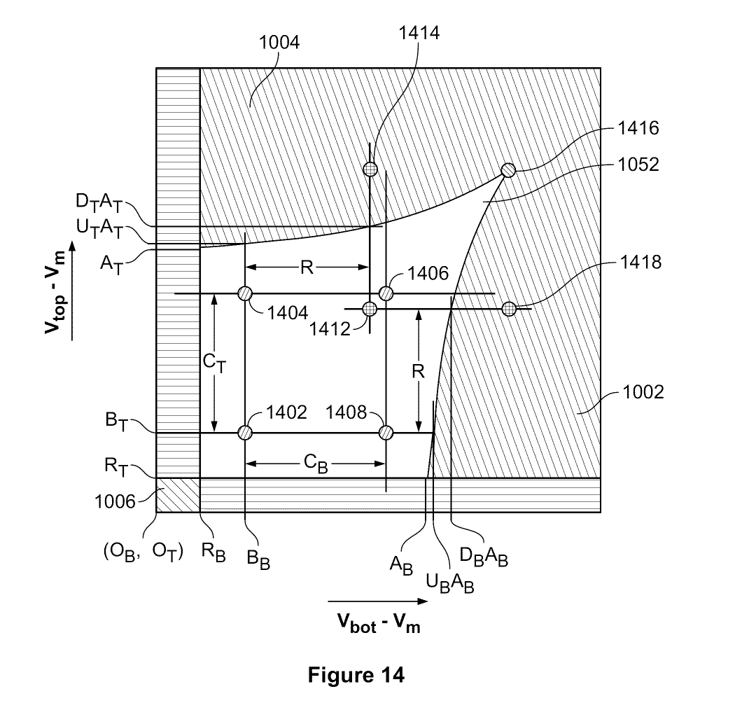

FIG. 14 illustrates an example of a diagram illustrating a movable middle layer position versus applied voltage for the interferometric modulator of FIG. 9. The diagram of FIG. 14 corresponds to a quadrant of the diagram described above with reference to FIG. 10. The various voltages values are described with reference to Table 1 below. The voltage values described below with respect to FIG. 14 are related to the voltages used for the example implementation of FIGS. 13A and 13B. The relationship between the values of these Figures and the parameters used in the explanation of FIG. 14 are set forth below.

TABLE 1

| Symbol | Reference |
|---|---|
| B_{B,} B_{T} | Bias for a given display element for bottom and top portions |
| | respectively (may be V_{bias} of FIG. 13B minus |
| | V_{col} of FIG. 13B) |
| C_{B}, C_{T} | Data pulse height for bottom and top portions respectively |
| | (may be common for display elements, may be 2 V_{col}, |
| | denoted 930 in FIG. 13B). |
| R | Scan pulse height above Bias (may be ΔV, denoted 928 in |
| | FIG. 13B) |
| A_{B} | Actuation voltage magnitude for given display element for |
| | bottom portion when voltage across top portion is zero. |
| A_{T} | Actuation voltage magnitude for given display element for top |
| | portion when voltage across bottom portion is zero. |
| U_{B}A_{B} and | Actuation voltage magnitude for given display element at |
| U_{T}A_{T} | bias voltage (inactive scan line) for bottom and top |
| | portions, respectively |
| D_{B}A_{B} and | Actuation voltage magnitude for bias + scan pulse |
| D_{T}A_{T} | (driven scan line) for bottom and top portions, respectively |
| R_{B,} R_{T} | Release voltage magnitude for bottom and top portions |
| | respectively (function of voltage on opposite portion) |

In Table 1, where B_{B}≠B_{T}, an offset between top and bottom segment voltage levels may be present. Alternatively, in some implementations, B_{B}=B_{T}, and C_{B}=C_{T}.

As shown in FIG. 14, voltage difference points 1402, 1404, 1406, and 1408 are within the stability window 1052. These four points correspond to the four different hold states in the second table portion from the top in FIG. 13A. As described below with reference to FIGS. 13A and 13B, a change in the applied voltage across portions of the display element 800 may shift the voltage point 1404 to be within a top actuation voltage window 1004 (as illustrated by voltage point 1414), and may also shift a voltage point 1408 to a bottom actuation voltage window 1002 (as illustrated by voltage point 1418). Further, the applied voltages may be set such that a voltage point 1402 may be shifted to voltage point 1412 so as to be maintained within the stability window 1052. This shift may be caused by the application of the write pulse 920 of FIG. 13B. As shown in FIG. 14, a voltage point 1406 may be shifted to a voltage point 1416, and a driver may be configured to avoid application of the combination of voltages that would result in a shift to the voltage point 1416 since the corners of the 2-dimensional hysteresis curve produce unpredictable behavior with small changes in applied voltage and starting position of the middle layer 806 resulting in widely different actuation behavior.

To actuate the display element to one of the top actuated position S2 and the bottom actuated position S3, the various values described above with respect to Table 1 and FIG. 14 may have relationships as shown below in Equation 2 for a top portion of the display element and Equation 3 for a bottom portion of the display element:

R_{B}<B_{B}<B_{B}+C_{B}<U_{B}A_{B}<D_{B}A_{B}<B_{B}+R+C_{B} and B_{B}<B_{B}+R<D_{B}A_{B} Eq. (2)

R_{T}<B_{T}<B_{T}+C_{T}<U_{T}A_{T}<D_{T}A_{T}<B_{T}+R+C_{T} and B_{T}<B_{T}+R<D_{T}A_{T} Eq. (3)

To release a display element (e.g. position the movable middle layer at position S1), the parameters may be configured as described with reference to Equation 4 below (in this and the other equations below, any parameter associated with a subscript min or max refers to the minimum or maximum of that value over all of the tri-state display elements of the array):

C_{B}<(R_{B})ₘᵢₙ+(R_{B}_{^{−}})ₘᵢₙ and

C_{T}<(R_{T})ₘᵢₙ+(R_{T}_{^{−}})ₘᵢₙ Eq. (4)

The voltage applied to a common line may impact the ratio of the gap height for the top and bottom portions of the display element 800. Further, a segment line pulse may impact the behavior of different display elements. In some implementations, the display elements 800 may be configured such that Equations 5-6 below are satisfied.

(D_{B}A_{B})ₘₐₓ−(U_{B}A_{B})ₘᵢₙ<R<(D_{B}A_{B})ₘᵢₙ−(R_{B})ₘₐₓ, and

(D_{T}A_{T})ₘₐₓ−(U_{T}A_{T})ₘᵢₙ<R<(D_{T}A_{T})ₘᵢₙ−(R_{T})ₘₐₓ Eq. (5)

D_{B}A_{B}<CB<(U_{B}A_{B})ₘᵢₙ−(R_{B})ₘₐₓ,

C_{B}<(R_{B})ₘᵢₙ+|(R_{B}_{^{−}})|ₘᵢₙ,

D_{T}ΔA_{T}<C_{T}<(U_{T}A_{T})ₘᵢₙ−(R_{T})ₘₐₓ, and

C_{T}<(R_{T})ₘᵢₙ+|(R_{T}_{^{−}})|ₘᵢₙ Eq. (6)

In some implementations, the display elements may be designed such that certain criteria are satisfied as outlined in Table 2 below:

TABLE 2

| Parameter | Relationship | Calibration | Definitions/Relationships |
|---|---|---|---|
| B_{X} = Bias | B_{B} > {R_{B}}max | For each sub- | AL ≡ Allowance |
| (per display element | B_{T} > {R_{T}}max | pixel: | (Margin against false |
| and display element | | B_{B} := {R_{B}}max + | releases) |
| portion, where X | | AL | Choosing minimum |
| corresponds to the top | | B_{T} := {R_{T}}max + | allowed value maximizes |
| or bottom portion) | | AL | the margin for SO_{C} (see |
| | | If forcing equal | below). |
| | | values: | |
| | | B_{B,}B_{T} := | |
| | | {{R_{B}}max, | |
| | | {R_{T}}ₘₐₓ}ₘₐₓ + AL | |
| R = Row pulse height | B_{B} + R < | For each sub- | D_{B}, D_{T} may be a |
| (per display element) | {DBAB}ₘᵢₙ | pixel: | function of (B_{X} + R). |
| | B_{T} + R < {D_{T}A_{T}}ₘᵢₙ | R = {{D_{B}A_{B}}ₘᵢₙ − | SO_{R} ≡ Standoff (Margin |
| | | B_{B}, {D_{T}A_{T}}ₘᵢₙ − | for false actuation on |
| | | B_{T}}ₘᵢₙ − SO_{R} | current row) |
| | | | Choosing maximum |
| | | | allowed value may |
| | | | maximizs the margin for |
| | | | O_{V} (see below). |
| C_{X} = Column swing | For each sub-pixel: | Compute C_{X} min | |
| (X = top or bottom | Upper limits 1: | and max from the | Allow for margin SO_{C} |
| portion) | B_{B} + C_{B} < | upper and lower | (Standoff) for upper |
| | {U_{B}A_{B}}ₘᵢₙ | limits, taking | limits 1 (Margin for false |
| | B_{T} + C_{T} < {U_{T}A_{T}}ₘᵢₙ | substantially all | actuation on non-current |
| | | display elements | rows) |
| | Upper limits 2: | into account, and | Allow for margin 2AL |
| | C_{B} < {R_{B}}ₘᵢₙ + | select the mean | (Allowance) for upper- |
| | {\|R_{B}−\|}ₘᵢₙ | value. | limits 2 (Margin to reset |
| | C_{T} < {R_{T}}ₘᵢₙ + | | display elements to |
| | {\|R_{T}−\|}ₘᵢₙ | | released state) |
| | Lower limits: | | Allow for margin OV |
| | B_{B} + R + C_{B} > | | (Over-voltage) for lower |
| | {D_{B}A_{B}}ₘₐₓ | | limits (Margin to actuate |
| | B_{T} + R + C_{T} > | | desired display elements |
| | {D_{T}A_{T}}ₘₐₓ | | on the current row) |
| Clear pulse height (S) | Upper limits: | Compute S min | Allow for margin AL |
| (X = top or bottom | S < B_{X} + {R_{X}}ₘᵢₙ | and max from the | (Allowance) for both |
| portion) | Lower limits: | upper and lower | upper and lower limits |
| | S > B_{X} + C_{X} − {R_{X}}ₘᵢₙ | limits, taking all | |
| | | display elements | |
| | | into account, and | |
| | | select the mean | |
| | | value. | |

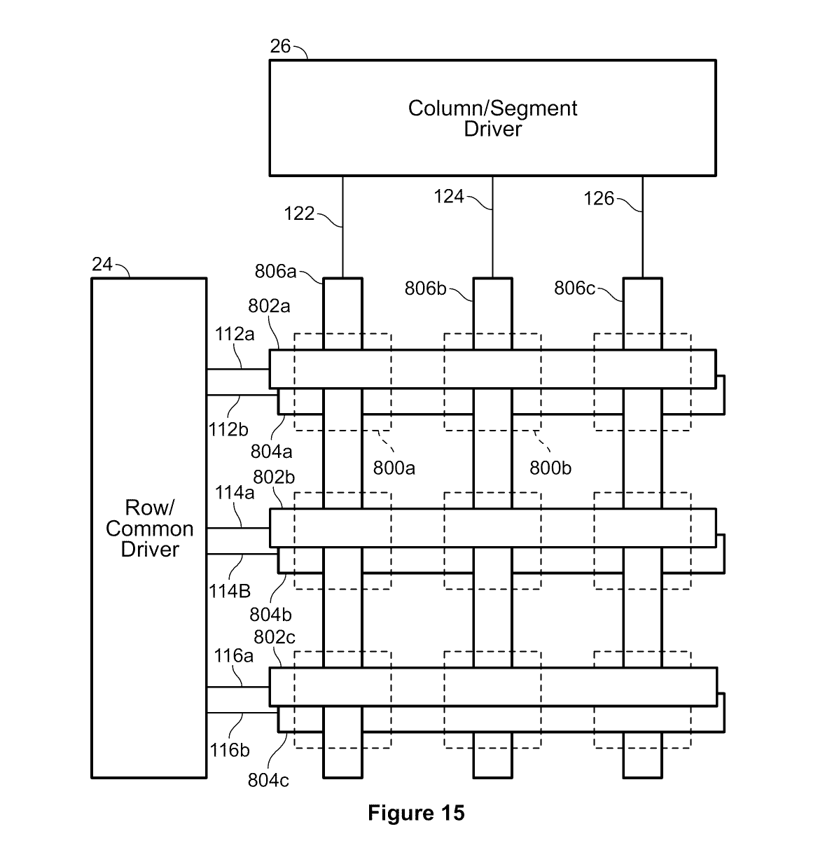

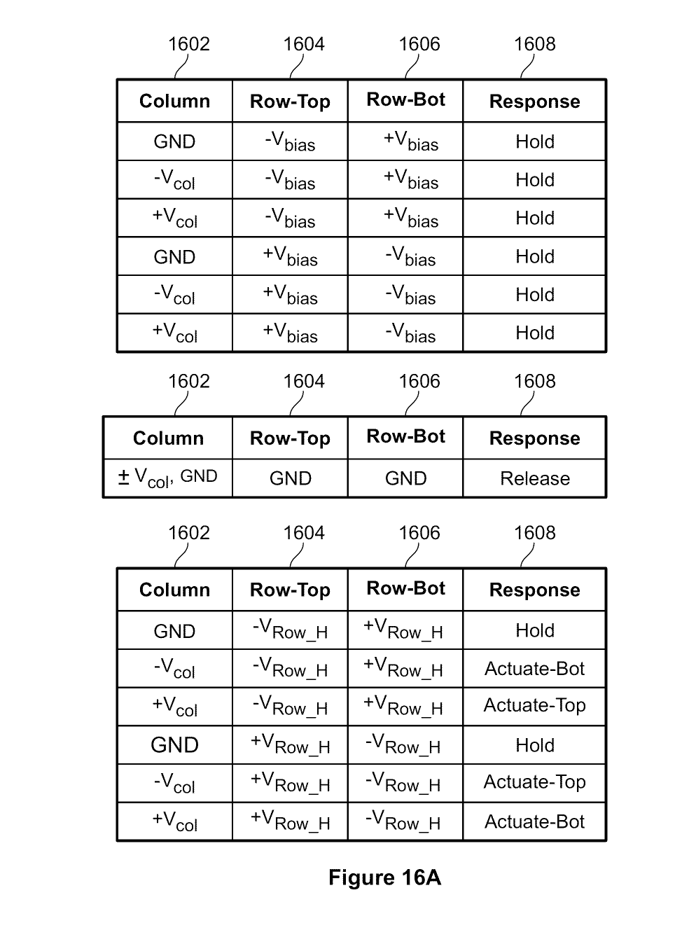

FIG. 15 illustrates an example of an array of tri-state display elements that can be written with a passive matrix drive scheme having two common lines and one segment line according to some implementations. As illustrated in FIG. 15, display elements 800 are formed at the intersections of the row electrodes and column electrodes arranged in an array. For example, a display element 800A is formed at the intersection of row electrodes 802A, 804A and column electrode 806A, while a display element 800B is formed at the intersection of row electrodes 802A, 804A and column electrode 806B. The array of FIG. 15 includes a 3×3 array of display elements 800. A person having ordinary skill in the art will recognize that the size of the array is not limited thereto.

As illustrated in FIG. 15, the row electrodes 802A and 802B correspond to the fixed first layer 802 (e.g., top electrode) and fixed second layer 804 (e.g., bottom electrode) as described above with reference to FIG. 9, while the column electrode 806A corresponds to the movable third layer 806 (e.g., middle electrode) of the display element 800. A tri-state passive matrix drive scheme may include a column/segment driver 26 configured to apply a voltage to the column electrodes 806A, 806B, and 806C directly through a plurality of segment lines (e.g., segment lines 122, 124, and 126). A row/common driver 24 may be configured to apply a voltage directly to the row electrodes 802A, 804A, 802B, 804B, 802C, and 804C through a plurality of common lines (e.g., first common lines 112A, 114A, 116A, and second common lines 112B, 114B, and 116B). As illustrated in FIG. 15, the array includes one segment line and two common lines for each display element 800. Each of the electrodes of each of the display elements 800 is directly connected to the driver lines in the tri-state passive matrix drive scheme.

In order to drive the tri-state elements in the configuration of FIG. 15, voltages for driving each layer 802, 804, and 806 of each display element 800 are configured such that false actuation of other display elements 800 in the array may not occur. For example, voltages are applied such that a display element 800B of FIG. 15 which is connected to the same common line 112 as a display element 800A to be driven is not inadvertently actuated while providing an actuation signal to the display element 800A.

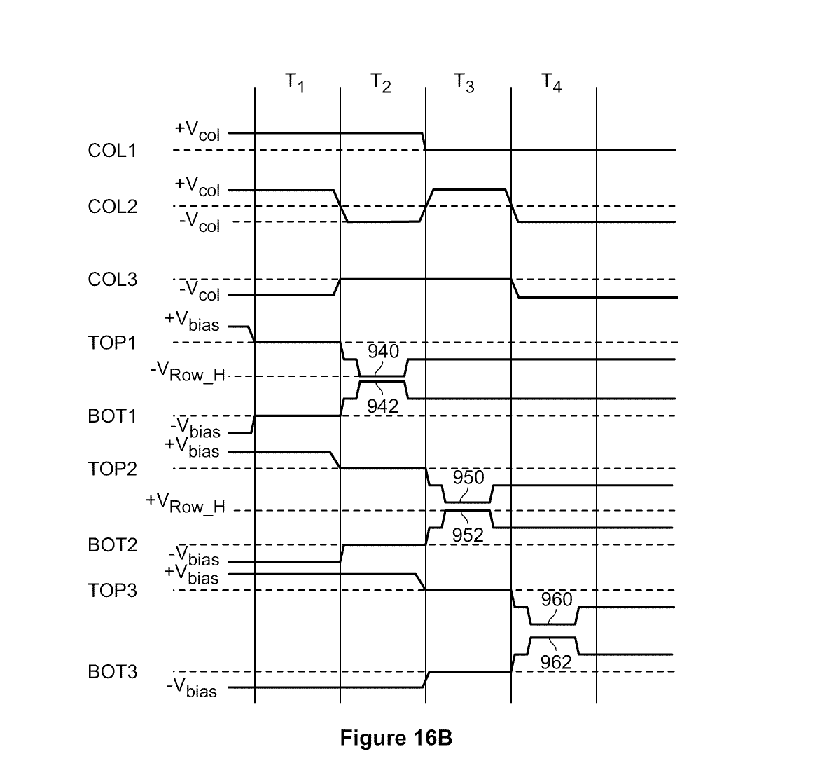

FIG. 16A is an example of voltages applied to the common lines and segment lines in a passive matrix drive scheme according to some implementations. As illustrated in FIG. 16A, the voltage applied to the segment lines (e.g., segment lines 122, 124, and 126 of FIG. 15) and along each column electrode are illustrated in column 1602. The voltages applied to the first common lines (e.g., common lines 112A, 114A, and 116A of FIG. 15) connected to the top electrode (e.g., row electrodes 802A, 802B, and 802C of FIG. 15) are illustrated in column 1604. The voltages applied to the second common lines (e.g., common lines 112B, 114B, and 116B of FIG. 15) connected to the bottom electrode (e.g., row electrodes 804A, 804B, and 804C of FIG. 15) are shown in column 1606. The response of a display element 800 having the voltages applied as illustrated in the table is shown in column 1608.

As shown in FIG. 16A, the row electrodes may be transitioned between voltages having values of +V_{Row}_{_{—}}_{H}, +V_{bias}, ground (GND), −V_{bias}, and −V_{Row}_{_{—}}_{H}, while the column electrodes may be transitioned between voltages having values of +V_{col}, ground (GND), and −V_{col}. The value of V_{Row}_{_{—}}_{H} may range from approximately 4V to 20V, while the value of V_{col} may range from approximately 2V to 20V. In the implementation of FIG. 16A, the magnitude of a write voltage V_{Row}_{_{—}}_{H} is equal to (V_{bias}+V_{W}). Further, the magnitude of each of the column voltage V_{col} and the voltage V_{W} is greater than the ΔV/4 and less than ΔV/2 such that ΔV/4<V_{col}<ΔV/2 and ΔV/4<V_{w}<ΔV/2. In some implementations, V_{col} may be equal to V. In one example, V_{col}=V_{w}=(¾)ΔV. These voltages values may be used to write data to rows of display elements 800 in the array while maintaining a current state of other rows of display elements 800 in the array during the write process.

As discussed above, and with returned reference to FIG. 3, the voltage level V_{bias} may correspond to the center of the hold or stability window corresponding to each half the display element 800. For example, a voltage difference V_{bias} between the movable third layer 806 and the fixed first layer 802 may correspond to the center of the stability window as illustrated in FIG. 3 for a top half of the display element 800. Similarly, a voltage difference V_{bias} between the movable third layer 806 and the fixed first layer 802 may correspond to the center of the stability window as illustrated in FIG. 3 for a bottom half of the display element 800. As shown in FIG. 16A, to maintain a current position of a display element, a bias voltage of a first polarity is applied to a row electrode (e.g., top or bottom electrode) while a bias voltage of the second polarity is applied to the other row electrode (e.g., the other of the top or bottom electrode) since the magnitude of V_{col} is less than ΔV. That is, the sum of V_{bias} and V_{col} corresponds to a potential difference across each half of the tri-state display element that is within the stability window as illustrated in FIG. 3. Further, a display element may be maintained in a current state by application of a ground voltage to the column electrode regardless of the voltage (e.g., +V_{Row}_{_{—}}_{H}, +V_{bias}, ground (GND), −V_{bias}, and −V_{Row}_{_{—}}_{H}) that is applied to the row electrodes.

To place a display element 800 in a released state, or a position S1 at which the movable third layer 806 is substantially centered between the fixed first layer 802 and the fixed second layer 804, a ground voltage (GND) may be applied to the row electrodes. Application of the ground voltage to the top and bottom electrodes releases the display element 800 since the magnitude of the column voltage V_{col} has a value such that a potential difference across the movable third layer 806 and either of the fixed first layer 802 and fixed second layer 804 is within the relaxed window.

To move the movable third layer 806 to an actuated top position S2 relative to the fixed first layer 802 (top electrode), a write voltage −V_{Row}_{_{—}}_{H} may be applied to the top electrode (e.g., fixed first layer 802) while a write voltage −V_{Row}_{_{—}}_{H} is applied to the bottom electrode (e.g., fixed second layer 804) and a column voltage +V_{col} is applied to middle electrode (e.g., movable third layer 806). To move the movable third layer 806 to an actuated bottom position S3 relative to the fixed second layer 804 (bottom electrode) a write voltage +V_{Row}_{_{—}}_{H} may be applied to the top electrode (e.g., fixed first layer 802) while a write voltage −V_{Row}_{_{—}}_{H} is applied to the bottom electrode (e.g., fixed second layer 804) and a column voltage +V_{col} is applied to middle electrode (e.g., movable third layer 806). Alternatively, column electrodes may be transitioned to a column voltage −V_{col}, and the configuration of the positive/negative voltages for the row electrodes would be reversed for the same display element response as shown in FIG. 16A.

FIG. 16B illustrates an example waveform for driving a display element by application of the voltages of FIG. 16A. The waveforms illustrated in FIG. 16B will be described in connection with the display array of FIG. 15, and are suitable for writing the data pattern of FIG. 12B. A person having ordinary skill in the art will recognize that the waveforms described with respect to FIG. 16B and similar waveforms may be applied to any number of display elements arranged in an array. As illustrated in FIG. 16B, the voltage applied on each of the six row electrodes is initially +V_{bias}. Each of the column electrodes are at either +V_{cols} or −V_{col}. This is a hold state for all the elements, which will be stable in whatever their current position is. During a first time period T₁, common electrodes 112A and 112B are brought to zero volts. This releases all the display elements along the first row. In a second time period T2, the segment driver 26 applies data signals to the three column electrodes, and the two common electrodes 112A and 112B of the first row are strobed with write pulses 940 and 942 of −V_{Row}_{_{—}}_{H} and +V_{Row}_{_{—}}_{H} respectively. These may be equal to −V_{bias}−(¾)ΔV and +V_{bias} (¾)ΔV as described above. As described above with respect to FIG. 16A, to actuate the first element of the first row to the top, the segment electrode 122 is set to +V_{col}. This will cause the first display element 800A of the first row to be actuated to the top electrode during the common line write pulses 920 and 940 on electrodes 112A and 112B during time T2. Similarly, the segment electrode 124 of the second display element 800B of the first row is set to −V_{col} prior to the write pulses 940 and 942 of electrodes 112A and 112B. This causes the second display element 800B of the first row to be actuated to the bottom electrode. For the third display element of the first row, the segment electrode 126 is set to zero volts prior to the row pulses 940 and 942. This maintains the released state of the third element (released during time period T1) during the row pulses 940 and 942 on the electrodes 112A and 112B. Also during time period T2, the row electrodes 114A and 114B are transitioned to zero volts, releasing the display elements of the second row in preparation for writing data to the second row. This process is sequentially repeated for the second and third rows with row pulses 950 and 952, and row pulses 960 and 962 applied to electrodes 114A/B and 116A/B respectively, where the voltages applied to the segment electrodes are suitable to cause top actuation, bottom actuation, or maintain a released state as described above with respect to the first row. Following completion of writing the desired data pattern to the array, the voltage on all row electrodes 112A/B, 114A/B, and 116A/B is +V_{bias} or −V_{bias}, and the voltage on each segment electrode is either −V_{col}, +V_{col}, or zero, such that each display element is in a hold state and the data pattern written is maintained. Although the waveforms of FIG. 16B are illustrated with top row electrodes 112A, 114A, and 116A having a negative voltage pulse, and with bottom row electrodes 112B, 114B, and 116B having a positive voltage pulse, these could be switched, wherein writing the same data would be accomplished using the opposite polarity segment voltages in each time period.

FIG. 17 illustrates an example of an array of tri-state display elements that can be driven with an active matrix drive scheme having plural common lines and one segment line connected to each display element according to some implementations. In the “active matrix” drive scheme shown in FIG. 17, a variable voltage may be applied to the top and bottom electrodes of each display element (corresponding to, for example, the fixed first layer 802 and the fixed second layer 804) through driving signals supplied by a row/common driver 24 to top and bottom row/common lines (e.g., Top1, Bot1, Top2, Bot2, Top3, Bot3). A variable voltage may also be applied to the movable third layer 806 through operation of isolating circuitry (e.g., transistor switches 1700) associated with each of the display elements. For example, a transistor switch output may be coupled to a middle electrode (e.g., 806A1-A3, 806B1-B3, and 806C1-C3) corresponding to the movable third layer 806 of each display element. An output of the row/common driver 24 may be connected to a gate terminal of the transistor switch 1700 through a gate line (e.g., GL1, GL2, and GL3), and may be provided as a signal to a gate terminal of the transistor switches 1700 connected to the movable third layer 806. The segment/column driver 26 may be configured to provide a data signal along a data or segment line (e.g., DL1, DL2, and DL3) to a first terminal of the transistor switches 1700. In this way, the transistor switches 1700 are configured as switches for providing a voltage to the middle electrode 806 based on an output of both the row/common driver 24 and the column/segment driver 26.

FIG. 18 illustrates an example waveform for driving a display element using an active matrix to write the data pattern of FIG. 12B. The waveforms illustrated in FIG. 18 will be described in connection with the display array of FIG. 17. A person having ordinary skill in the art will recognize that the waveforms described with respect to FIG. 18 and similar waveforms may be applied to any number of display elements arranged in an array. As illustrated in FIG. 18, the voltage applied on each of the three top row electrodes is initially +V_{Row}_{_{—}}_{H}, while the voltage applied on each of the three bottom row electrodes is initially −V_{Row}_{_{—}}_{H}, and each of the gate lines GL1, GL2, and GL3 is set such that the transistor switches 1700 are in an open state (e.g., non-conductive state). Each of the column electrodes are driven with data lines (DL1, DL2, and DL3) at either +V_{cols} or −V_{col}. This is a hold state for all the elements, which will remain substantially stable in whatever their current position is.

During a first time period T₁, common electrodes Top1 and Bot1 are brought to zero volts and the gate line GL1 is asserted to drive the switches along the first row to a closed or conductive state. This releases all the display elements along the first row. In a second time period T2, the segment driver 26 applies data signals to the three column electrodes, and the two common lines Top1 and Bot1 of the first row are strobed with write pulses of −V_{Row}_{_{—}}_{H} and +V_{Row}_{_{—}}_{H} respectively. As discussed above with reference to FIG. 16B, these voltages may be equal to −V_{bias}−(\vec{3/4})ΔV and +V_{bias}+(\vec{3/4})ΔV. Further, during time period T2, the gate line GL1 connected to transistor switches along the first row remains asserted. As a result, the voltage along the data lines DL1, DL2, and DL3 is applied to the display elements along the first row. Since the voltage on DL1 corresponds to the +V_{col}, the application of the voltages to the common and gate lines will cause the first display element of the first row to be actuated to the top position S2 during time period T2. Similarly, the data line DL2 of the second display element of the first row is set to −V_{col} prior to application of write pulses and application of the gate line signal, which causes the second display element of the first row to be actuated to the bottom electrode. For the third display element of the first row, the data line DL3 is set to zero volts prior to the application of the write pulses to the common lines and the gate signal to the gate line. This maintains the released state of the third display element (which was released during time period T1) during time period T2. Also during time period T2, the common lines Top2 and Top3 are transitioned to zero volts and the gate line GL2 is asserted to drive the switches along the second row to a closed or conductive state, releasing the display elements of the second row in preparation for writing data to the second row. This process is sequentially repeated for the second and third rows, where the voltages applied to the segment electrodes are suitable to cause top actuation, bottom actuation, or maintain a released state as described above with respect to the first row. Following completion of writing the desired data pattern to the array, the voltage applied to each gate line GL1, GL2, and GL3 is set to 0V, such that each transistor switches 1700 are in an open or non-conductive state, and each display element is in a hold state. As a result, the data pattern written is maintained. Although the waveforms of FIG. 18 are illustrated with top electrodes having a negative voltage pulse, and with bottom electrodes having a positive voltage pulse, these could be switched, such that writing the same data would be accomplished using the opposite polarity data line voltages in each time period.

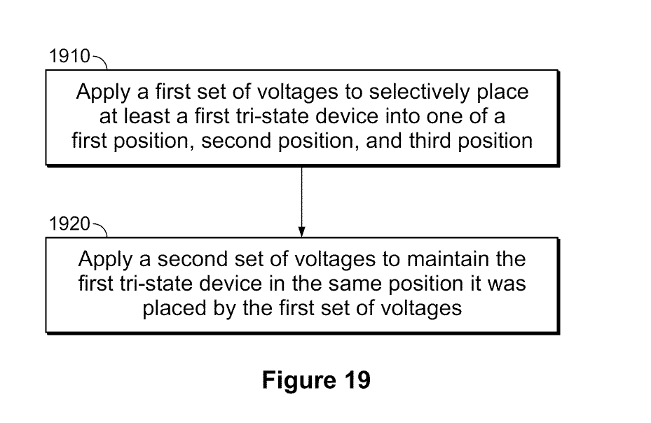

FIG. 19 illustrates a flowchart of a method of driving an array of display elements according to some implementations. The method of FIG. 19 takes advantage of the hold states of FIG. 10 to utilize a “tri-stable” rather than a bistable device in an array. In this method, at block 1910, a first set of voltages are applied to selectively place at least a first tri-state device into one of a first position, second position, and third position. At block 1920, a second set of voltages are applied to maintain the first tri-state device in the same position it was placed by the first set of voltages.

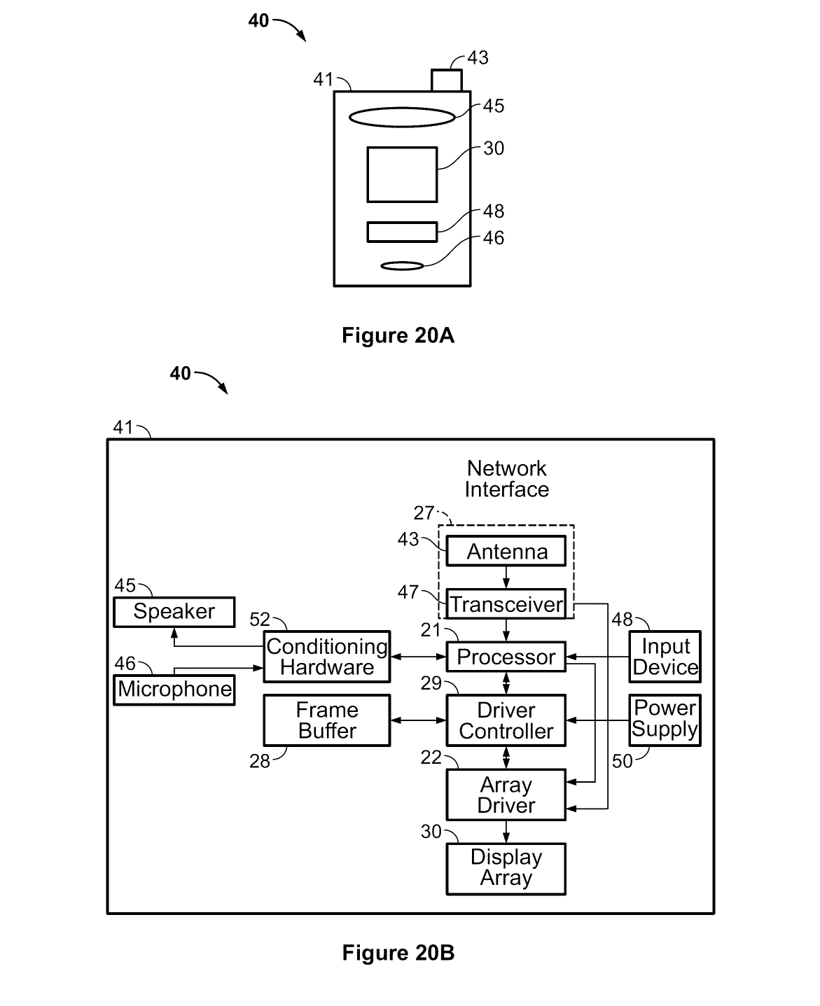

FIGS. 20A and 20B show examples of system block diagrams illustrating a display device 40 that includes a plurality of interferometric modulators. The display device 40 can be, for example, a cellular or mobile telephone. However, the same components of the display device 40 or slight variations thereof are also illustrative of various types of display devices such as televisions, e-readers and portable media players.

The display device 40 includes a housing 41, a display 30, an antenna 43, a speaker 45, an input device 48, and a microphone 46. The housing 41 can be formed from any of a variety of manufacturing processes, including injection molding, and vacuum forming. In addition, the housing 41 may be made from any of a variety of materials, including, but not limited to: plastic, metal, glass, rubber, and ceramic, or a combination thereof. The housing 41 can include removable portions (not shown) that may be interchanged with other removable portions of different color, or containing different logos, pictures, or symbols.

The display 30 may be any of a variety of displays, including a bi-stable or analog display, as described herein. The display 30 also can be configured to include a flat-panel display, such as plasma, EL, OLED, STN LCD, or TFT LCD, or a non-flat-panel display, such as a CRT or other tube device. In addition, the display 30 can include an interferometric modulator display, as described herein.

The components of the display device 40 are schematically illustrated in FIG. 20B. The display device 40 includes a housing 41 and can include additional components at least partially enclosed therein. For example, the display device 40 includes a network interface 27 that includes an antenna 43 which is coupled to a transceiver 47. The transceiver 47 is connected to a processor 21, which is connected to conditioning hardware 52. The conditioning hardware 52 may be configured to condition a signal (e.g., filter a signal). The conditioning hardware 52 is connected to a speaker 45 and a microphone 46. The processor 21 is also connected to an input device 48 and a driver controller 29. The driver controller 29 is coupled to a frame buffer 28, and to an array driver 22, which in turn is coupled to a display array 30. A power supply 50 can provide power to all components as required by the particular display device 40 design.

The network interface 27 includes the antenna 43 and the transceiver 47 so that the display device 40 can communicate with one or more devices over a network. The network interface 27 also may have some processing capabilities to relieve, e.g., data processing requirements of the processor 21. The antenna 43 can transmit and receive signals. In some implementations, the antenna 43 transmits and receives RF signals according to the IEEE 16.11 standard, including IEEE 16.11(a), (b), or (g), or the IEEE 802.11 standard, including IEEE 802.11a, b, g or n. In some other implementations, the antenna 43 transmits and receives RF signals according to the BLUETOOTH standard. In the case of a cellular telephone, the antenna 43 is designed to receive code division multiple access (CDMA), frequency division multiple access (FDMA), time division multiple access (TDMA), Global System for Mobile communications (GSM), GSM/General Packet Radio Service (GPRS), Enhanced Data GSM Environment (EDGE), Terrestrial Trunked Radio (TETRA), Wideband-CDMA (W-CDMA), Evolution Data Optimized (EV-DO), NEV-DO, EV-DO Rev A, EV-DO Rev B, High Speed Packet Access (HSPA), High Speed Downlink Packet Access (HSDPA), High Speed Uplink Packet Access (HSUPA), Evolved High Speed Packet Access (HSPA+), Long Term Evolution (LTE), AMPS, or other known signals that are used to communicate within a wireless network, such as a system utilizing 3G or 4G technology. The transceiver 47 can pre-process the signals received from the antenna 43 so that they may be received by and further manipulated by the processor 21. The transceiver 47 also can process signals received from the processor 21 so that they may be transmitted from the display device 40 via the antenna 43.

In some implementations, the transceiver 47 can be replaced by a receiver. In addition, the network interface 27 can be replaced by an image source, which can store or generate image data to be sent to the processor 21. The processor 21 can control the overall operation of the display device 40. The processor 21 receives data, such as compressed image data from the network interface 27 or an image source, and processes the data into raw image data or into a format that is readily processed into raw image data. The processor 21 can send the processed data to the driver controller 29 or to the frame buffer 28 for storage. Raw data typically refers to the information that identifies the image characteristics at each location within an image. For example, such image characteristics can include color, saturation, and gray-scale level.

The processor 21 can include a microcontroller, CPU, or logic unit to control operation of the display device 40. The conditioning hardware 52 may include amplifiers and filters for transmitting signals to the speaker 45, and for receiving signals from the microphone 46. The conditioning hardware 52 may be discrete components within the display device 40, or may be incorporated within the processor 21 or other components.

The driver controller 29 can take the raw image data generated by the processor 21 either directly from the processor 21 or from the frame buffer 28 and can re-format the raw image data appropriately for high speed transmission to the array driver 22. In some implementations, the driver controller 29 can re-format the raw image data into a data flow having a raster-like format, such that it has a time order suitable for scanning across the display array 30. Then the driver controller 29 sends the formatted information to the array driver 22. Although a driver controller 29, such as an LCD controller, is often associated with the system processor 21 as a stand-alone Integrated Circuit (IC), such controllers may be implemented in many ways. For example, controllers may be embedded in the processor 21 as hardware, embedded in the processor 21 as software, or fully integrated in hardware with the array driver 22.

The array driver 22 can receive the formatted information from the driver controller 29 and can re-format the video data into a parallel set of waveforms that are applied many times per second to the hundreds, and sometimes thousands (or more), of leads coming from the display's x-y matrix of pixels.

In some implementations, the driver controller 29, the array driver 22, and the display array 30 are appropriate for any of the types of displays described herein. For example, the driver controller 29 can be a conventional display controller or a bi-stable display controller (e.g., an IMOD controller). Additionally, the array driver 22 can be a conventional driver or a bi-stable display driver (e.g., an IMOD display driver). Moreover, the display array 30 can be a conventional display array or a bi-stable display array (e.g., a display including an array of IMODs). In some implementations, the driver controller 29 can be integrated with the array driver 22. Such an implementation is common in highly integrated systems such as cellular phones, watches and other small-area displays.

In some implementations, the input device 48 can be configured to allow, e.g., a user to control the operation of the display device 40. The input device 48 can include a keypad, such as a QWERTY keyboard or a telephone keypad, a button, a switch, a rocker, a touch-sensitive screen, or a pressure- or heat-sensitive membrane. The microphone 46 can be configured as an input device for the display device 40. In some implementations, voice commands through the microphone 46 can be used for controlling operations of the display device 40.

The power supply 50 can include a variety of energy storage devices as are well known in the art. For example, the power supply 50 can be a rechargeable battery, such as a nickel-cadmium battery or a lithium-ion battery. The power supply 50 also can be a renewable energy source, a capacitor, or a solar cell, including a plastic solar cell or solar-cell paint. The power supply 50 also can be configured to receive power from a wall outlet.

In some implementations, control programmability resides in the driver controller 29 which can be located in several places in the electronic display system. In some other implementations, control programmability resides in the array driver 22. The above-described optimization may be implemented in any number of hardware and/or software components and in various configurations.

The various illustrative logics, logical blocks, modules, circuits and algorithm steps described in connection with the implementations disclosed herein may be implemented as electronic hardware, computer software, or combinations of both. The interchangeability of hardware and software has been described generally, in terms of functionality, and illustrated in the various illustrative components, blocks, modules, circuits and steps described above. Whether such functionality is implemented in hardware or software depends upon the particular application and design constraints imposed on the overall system.

The hardware and data processing apparatus used to implement the various illustrative logics, logical blocks, modules and circuits described in connection with the aspects disclosed herein may be implemented or performed with a general purpose single- or multi-chip processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, or, any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration. In some implementations, particular steps and methods may be performed by circuitry that is specific to a given function.

In one or more aspects, the functions described may be implemented in hardware, digital electronic circuitry, computer software, firmware, including the structures disclosed in this specification and their structural equivalents thereof, or in any combination thereof. Implementations of the subject matter described in this specification also can be implemented as one or more computer programs, i.e., one or more modules of computer program instructions, encoded on a computer storage media for execution by, or to control the operation of, data processing apparatus.

If implemented in software, the functions may be stored on or transmitted over as one or more instructions or code on a computer-readable medium. The steps of a method or algorithm disclosed herein may be implemented in a processor-executable software module which may reside on a computer-readable medium. Computer-readable media includes both computer storage media and communication media including any medium that can be enabled to transfer a computer program from one place to another. A storage media may be any available media that may be accessed by a computer. By way of example, and not limitation, such computer-readable media may include RAM, ROM, EEPROM, CD-ROM or other optical disk storage, magnetic disk storage or other magnetic storage devices, or any other medium that may be used to store desired program code in the form of instructions or data structures and that may be accessed by a computer. Also, any connection can be properly termed a computer-readable medium. Disk and disc, as used herein, includes compact disc (CD), laser disc, optical disc, digital versatile disc (DVD), floppy disk, and blu-ray disc where disks usually reproduce data magnetically, while discs reproduce data optically with lasers. Combinations of the above should also be included within the scope of computer-readable media. Additionally, the operations of a method or algorithm may reside as one or any combination or set of codes and instructions on a machine readable medium and computer-readable medium, which may be incorporated into a computer program product.

Various modifications to the implementations described in this disclosure may be readily apparent to those skilled in the art, and the generic principles defined herein may be applied to other implementations without departing from the spirit or scope of this disclosure. Thus, the claims are not intended to be limited to the implementations shown herein, but are to be accorded the widest scope consistent with this disclosure, the principles and the novel features disclosed herein. The word “exemplary” is used exclusively herein to mean “serving as an example, instance, or illustration.” Any implementation described herein as “exemplary” is not necessarily to be construed as preferred or advantageous over other implementations. Additionally, a person having ordinary skill in the art will readily appreciate, the terms “upper” and “lower” are sometimes used for ease of describing the figures, and indicate relative positions corresponding to the orientation of the figure on a properly oriented page, and may not reflect the proper orientation of the IMOD as implemented.

Certain features that are described in this specification in the context of separate implementations also can be implemented in combination in a single implementation. Conversely, various features that are described in the context of a single implementation also can be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Further, the drawings may schematically depict one more example processes in the form of a flow diagram. However, other operations that are not depicted can be incorporated in the example processes that are schematically illustrated. For example, one or more additional operations can be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

1. An apparatus comprising:
a microelectromechanical systems (MEMS) device having a first layer, a second layer, and a movable third layer between the first layer and the second layer, the movable third layer configured to be positioned in one of a first position, a second position that is different than the first position, and a third position that is different than the first position and second position; and
a driver configured to apply a first set of voltages to the MEMS device to selectively place the device into one of the first position, second position, and third position, wherein the driver is further configured to apply a second set of voltages to the device to maintain the device in the same position it was placed by the first set of voltages.

2. The apparatus as recited in claim 1, further including an array of MEMS devices, wherein the driver is configured to apply voltages such that a first device is maintained in one of the first position, the second position, and the third position while changing a position of a second device.

3. The apparatus as recited in claim 1, wherein each of the first layer, the second layer, and the movable third layer are connected either directly or through a switch to one of a plurality common lines and a plurality of segment lines.

4. The apparatus of claim 3, wherein the driver is configured for passive addressing of an array of MEMS devices.

5. The apparatus as recited in claim 1, wherein the driver includes a common driver and a segment driver configured to drive an array of MEMS devices.

6. The apparatus as recited in claim 3, further comprising:
an array of MEMS devices;
a plurality of switches; and
a plurality of gate lines, each switch having an output that is connected to the movable third layer, a voltage signal input that is connected to a segment line, and a gate input that is connected to a gate line, and wherein the driver is configured to drive the plurality of gate lines to selectively apply a voltage level at the voltage signal input of a switch to a movable third layer when writing data to a device associated with the switch.

7. The apparatus as recited in claim 1, further comprising:
a plurality of first electrodes;
a plurality of second electrodes; and
a plurality of third electrodes, wherein the first layer, the second layer, and the movable third layer of the MEMS device corresponds to one of the plurality of first electrodes, the plurality of second electrodes, and the plurality of third electrodes.

8. The apparatus as recited in claim 7, wherein each of the plurality of first electrodes are directly connected to a first one of a plurality of segment lines, each of the plurality of second electrodes is directly connected to a second one of the plurality of segment lines, and each of the plurality of third electrodes is directly connected to a first one of a plurality of common lines.

9. The apparatus as recited in claim 7, wherein each of the plurality of first electrodes are directly connected to a first one of a plurality of segment lines, each of the plurality of second electrodes is directly connected to a first one of a plurality of common lines, and each of the plurality of third electrodes is directly connected to a second one of the plurality of common lines.

10. The apparatus as recited in claim 1, wherein the movable third layer is directly connected to a first one of a plurality of common lines, the first layer is directly connected to a first one of a plurality of segment lines, and the second layer is directly connected to a second one of the plurality of segment lines that is different than the first segment line.

11. The apparatus as recited in claim 1, wherein the movable third layer is directly connected to a first one of a plurality of segment lines, the first layer is directly connected to a first one of a plurality of common lines, and the second layer is directly connected to a second one of the plurality of common lines that is different than the first common line.

12. The apparatus as recited in claim 1, wherein the first layer and the second layer have a fixed position.

13. The apparatus as recited in claim 1, wherein the MEMS device forms a display element.

14. The apparatus as recited in claim 1, further comprising:
a display including an array of MEMS devices;
a processor that is configured to communicate with the display, the processor being configured to process image data; and
a memory device that is configured to communicate with the processor.

15. The apparatus as recited in claim 14, wherein the driver includes a common driver and a segment driver configured to send at least one signal to the display.

16. The apparatus as recited in claim 15, further comprising:
a controller configured to send at least a portion of the image data to the driver.

17. The apparatus as recited in claim 14, further comprising:
an image source module configured to send the image data to the processor.

18. The apparatus as recited in claim 17, wherein the image source module includes at least one of a receiver, transceiver, and transmitter.

19. The apparatus as recited in claim 14, further comprising:
an input device configured to receive input data and to communicate the input data to the processor.

20. A method of driving a microelectromechanical systems (MEMS) device, the MEMS device having a first layer, a second layer, and a movable third layer between the first layer and the second layer, the movable third layer configured to be positioned in one of a first position, a second position that is different than the first position, and a third position that is different than the first position and second position, the method comprising:
applying a first set of voltages to the MEMS device to selectively place the MEMS device into one of the first position, second position, and third position; and
applying a second set of voltages to the MEMS device to maintain the device in the same position it was placed by the first set of voltages.

21. The method as recited in claim 20, further including applying voltages to an array of MEMS devices such that a first device is maintained in one of the first position, the second position, and the third position while changing a position of a second device.

22. The method as recited in claim 20, wherein applying the first set of voltages and the second set of voltages includes applying voltages to each of the first layer, the second layer, and the movable third layer directly for passive addressing.

23. The method as recited in claim 20, further comprising selectively applying a voltage signal of the first set of voltages to the movable third layer based on a switching signal.

24. The method as recited in claim 20, wherein the MEMS device forms a display element, and wherein applying the first set of voltages includes writing image data.

25. The method as recited in claim 24, wherein applying the second set of voltages includes holding image data on the display element.

26. An apparatus comprising:
a microelectromechanical systems (MEMS) device having a first layer, a second layer, and a movable third layer between the first layer and the second layer, the movable third layer configured to be positioned in one of a first position, a second position that is different than the first position, and a third position that is different than the first position and second position:
means for applying a first set of voltages to the MEMS device to selectively place the MEMS device into one of the first position, second position, and third position; and
means for applying a second set of voltages to the MEMS device to maintain the device in the same position it was placed by the first set of voltages.

27. The apparatus as recited in claim 26, wherein the means for applying the first set of voltages and the means for applying the second set of voltages includes a common driver and a segment driver.

28. The apparatus as recited in claim 26, wherein the means for applying the first set of voltages and the second set of voltages includes means for applying voltages to each of the first layer, the second layer, and the movable third layer directly for passive addressing.

29. The apparatus as recited in claim 26, further comprising means for selectively applying a voltage signal of the first set of voltages to the movable third layer based on a switching signal.

30. The apparatus as recited in claim 26, wherein the MEMS device forms a display element.

31. The apparatus as recited in claim 26, wherein the first layer and the second layer have fixed positions.
